(19) United States
(12) Patent Application Publication
(10) Pub. No.: US 2026/0362841 A1
(43) Pub. Date: Nov. 12, 2026

(54) IMAGE SENSOR INCLUDING A REDISTRIBUTION STRUCTURE

(71) Applicant: Samsung Electronics Co., Ltd., Suwon-si (KR)

(72) Inventors: HYOUN-JEE HA, Suwon-si (KR); CHAE LYOUNG KIM, Suwon-si (KR); JEON IL LEE, Suwon-Si (KR)

(21) Appl. No.: 19/448,829

(22) Filed: Jan. 14, 2026

(30) Foreign Application Priority Data
May 7, 2025 (KR) 10-2025-0059004

(51) Int. Cl. H10F 39/95; H10F 39/00; H10F 39/18; H10W 46/00

(52) U.S. Cl. CPC H10F 39/95; H10F 39/182; H10F 39/811; H10W 46/301

(57) ABSTRACT

An image sensor includes first and second memory dies having first and second heights, respectively, the second height less than the first height, a molding material surrounding the first and second memory dies, a redistribution structure disposed on the first and the second memory dies and the molding material and including a first bonding dielectric layer, and a plurality of first bonding pads, wherein the redistribution structure has a first thickness in the vertical direction on the first memory die, and a second thickness on the second memory die greater than the first thickness, a logic die disposed on the redistribution structure and including a second bonding dielectric layer directly bonded to the first bonding dielectric layer, and a plurality of second bonding pads directly bonded to the plurality of first bonding pads, and an image sensor die on the logic die.

### CROSS-REFERENCE TO RELATED APPLICATION

This application claims priority to and the benefit of Korean Patent Application No. 10-2025-0059004 filed with the Korean Intellectual Property Office on May 7, 2025, the entire contents of which are incorporated herein by reference.

### BACKGROUND OF THE INVENTION

### a Field of the Invention

The present disclosure relates to an image sensor including a redistribution structure.

### B DESCRIPTION OF THE RELATED ART

The image sensor is a semiconductor device designed to convert an optical signal, which enters through a lens and includes two-dimensional or three-dimensional image information regarding an object, into an electrical signal. An image sensor generates an image of an object using a photoelectric conversion element that responds according to the intensity of light reflected from the object.

As artificial intelligence (AI) technology advances, in the field of image sensors, technology is being researched and developed in which edge artificial intelligence (edge AI) is embedded in the image sensor so that the image sensor may perform real-time detection, recognition, collection, classification, and tracking of objects or events without connection to an external high-performance processor, external memory, or cloud server. When an image sensor having embedded edge artificial intelligence (edge AI) is used, image data may be processed in real time, thereby enabling immediate application of the image data without delay, and reducing the risk of information leakage of the image data. In addition, when an image sensor having edge artificial intelligence (edge AI) embedded therein is used, since the image data may not need to be transmitted to a high-performance processor, external memory, or cloud server, network bandwidth may be reduced and power consumption may be reduced.

However, an image sensor including edge artificial intelligence (edge AI) requires, in addition to the region of logic for the functions of edge artificial intelligence (edge AI), a memory region necessary for edge artificial intelligence (edge AI) to perform learning and inference, and therefore, the image sensor including edge artificial intelligence (edge AI) inevitably has a size larger than that of a general image sensor.

As one solution to this problem, the wafer (panel) on which image sensor packages are formed and the wafer (panel) on which memory packages are formed may undergo hybrid bonding to form a wafer (panel) to wafer (panel) bonded structure, and chip scale package (CSP) packaging methods for manufacturing image sensors by singulating the structure may be applied to the manufacturing process of the image sensor. When manufacturing an image sensor by a CSP packaging method to which such hybrid bonding is applied, the size of the image sensor having edge artificial intelligence (edge AI) may be reduced, the mounting density of semiconductor dies within the image sensor may be improved, and signal transmission paths and power transmission paths between the semiconductor dies may be shortened.

Hybrid bonding should be performed in a state in which the bonding surface of the wafer (panel) where image sensor packages are formed and the bonding surface of the wafer (panel) where memory packages are formed are planarized. Specifically, it is appropriate that the surface roughness of the bonding surface of the wafer (panel) for performing hybrid bonding and the surface roughness of the bonding surface of the wafer (panel) on which memory packages are formed are 10Å or less, and if hybrid bonding is performed on a wafer (panel) on which image sensor packages that do not satisfy these criteria are formed and a wafer (panel) on which memory packages are formed, the vertical lines of the bonding surfaces to be bonded may not align.

Meanwhile, as described above, a memory package of an image sensor having edge artificial intelligence (edge AI) embedded therein may require a plurality of memory dies to support the learning and inference execution of the edge artificial intelligence (edge AI). However, even if the memory dies are formed on a single wafer, the memory dies may have different heights as a result of the accumulation of the surface topography of each layer inside each memory die, and due to such height differences of the memory dies, the bonding surface of the wafer (panel) on which the memory packages are formed may have a surface roughness value unsuitable for performing hybrid bonding.

### SUMMARY OF THE INVENTION

The problem to be solved by the present disclosure is to provide an image sensor including a memory package in which a redistribution layer (RDL) structure is formed on a plurality of memory dies.

The present disclosure provides an image sensor including an image sensor package including a memory package including a molding material having excellent thermal conductivity, or heat dissipation structures, and including dummy structures thermally connected to the molding material and the heat dissipation structures of a memory structure.

The problem to be solved by the present disclosure is to provide an image sensor including a redistribution structure including alignment marks for alignment between a plurality of memory dies and the redistribution structure, and alignment marks for alignment between the redistribution structure and an image sensor package.

According to an aspect of the present disclosure, an image sensor includes first and second memory dies having first and second heights, respectively, the second height less than the first height, a molding material surrounding the first and second memory dies, a redistribution structure disposed on the first and the second memory dies and the molding material and including a first bonding dielectric layer, and a plurality of first bonding pads, wherein the redistribution structure has a first thickness in the vertical direction on the first memory die, and a second thickness on the second memory die greater than the first thickness, a logic die disposed on the redistribution structure and including a second bonding dielectric layer directly bonded to the first bonding dielectric layer, and a plurality of second bonding pads directly bonded to the plurality of first bonding pads, and an image sensor die on the logic die.

According to an aspect of the present disclosure, an image sensor includes a memory package, and an image sensor package on the memory package. The memory package includes a molding material, a plurality of memory dies including a first memory die having an upper surface coplanar with an upper surface of the molding material and a second memory die having an upper surface lower than the upper surface of the molding material and adjacent to the first memory die, the plurality of memory dies having different heights in a vertical direction perpendicular to the upper surface of the molding material, and a redistribution structure disposed on the molding material and on the plurality of memory dies, contacting an upper surface of each of the plurality of memory dies, having a thickness profile with different thickness values in the vertical direction, and including a first bonding dielectric layer and a plurality of first bonding pads penetrating the first bonding dielectric layer, wherein a thickness of the redistribution structure on the first memory die is lower than a thickness of the redistribution structure on the second memory die. The image sensor package includes a logic die including a second bonding dielectric layer directly bonded to the first bonding dielectric layer and a plurality of second bonding pads penetrating the second bonding dielectric layer and directly bonded to the plurality of first bonding pads, and an image sensor die on the logic die.

According to an aspect of the present disclosure, an image sensor includes a first semiconductor package and a second semiconductor package on the first semiconductor package. The first semiconductor package includes a dummy die, a first memory die on the dummy die, the first memory die including a first surface in contact with the dummy die and a second surface opposite to the first surface, the first memory die having a first height between the first surface and the second surface, a second memory die on the dummy die and next to the first memory die, the second memory die including a third surface in contact with the dummy die and a fourth surface opposite to the third surface, the second memory die having a second height between the third surface and the fourth surface, the second height being less than the first height, a redistribution structure on the first memory die and on the second memory die, the redistribution structure including an etch stop layer, a redistribution layer on the etch stop layer, and a first bonding layer on the redistribution layer, the etch stop layer being in contact with the second surface and the fourth surface, the first bonding layer including a first bonding dielectric layer and a plurality of first bonding pads penetrating the first bonding dielectric layer, the redistribution structure having a first thickness on the first memory die and a second thickness on the second memory die, and the second thickness being greater than the first thickness, a first molding material surrounding a sidewall of each of the first memory die and the second memory die and disposed in a space between the dummy die and the redistribution structure, and a second molding material surrounding a sidewall of the first molding material and disposed in a space between the dummy die and the redistribution structure. The second semiconductor package includes a logic die including a second bonding layer, and an image sensor die on the logic die. The second bonding layer includes a second bonding dielectric layer directly bonded to the first bonding dielectric layer, and a plurality of second bonding pads penetrating the second bonding dielectric layer and directly bonded to the plurality of first bonding pads.

A method of manufacturing an image sensor according to the present disclosure may include: forming a memory package, the forming the memory package including attaching a plurality of memory dies having different heights from each other on a support substrate; molding the plurality of memory dies on the support substrate with a molding material; exposing upper surfaces of the plurality of memory dies; and forming a redistribution structure on the plurality of memory dies and on the molding material, the redistribution structure having a thickness profile having different thickness values on each of the plurality of memory dies, and the redistribution structure including a first bonding dielectric layer and a plurality of first bonding pads penetrating the first bonding dielectric layer; and bonding an image sensor package including a logic die including a second bonding dielectric layer and a plurality of second bonding pads penetrating the second bonding dielectric layer, and an image sensor die on the logic die, to the redistribution package, the second bonding dielectric layer being directly bonded to the first bonding dielectric layer, and each of the plurality of second bonding pads being directly bonded to a corresponding first bonding pad among the plurality of first bonding pads—.

(2) The method according to (1), wherein the molding with a molding material may include molding the plurality of memory dies with a first molding material on the support substrate; and molding the first molding material with a second molding material.

(3) The method according to (2), the first molding material may include a high dielectric constant (High-K) dielectric material.

(4) The method according to (2), wherein the second molding material may include an epoxy molding compound (EMC).

(5) The method according to (1), wherein the redistribution structure, the logic die, and the image sensor die each include a plurality of dummy structures, and the first molding material may be thermally connected to the plurality of dummy structures.

In a wafer (panel) in which memory packages formed are subjected to hybrid bonding together with a wafer (panel) in which image sensor packages are formed, a redistribution structure may be formed on a plurality of memory dies having different heights in a vertical direction from each other. As a result, the size (height) variation of the plurality of memory dies may be alleviated by the redistribution structure, the surface topography of the bonding surface of the wafer (panel) on which the memory packages are formed may be improved, and thus, the bonding quality between the wafer (panel) on which the image sensor packages to undergo hybrid bonding are formed and the wafer (panel) on which the memory packages are formed may be enhanced.

By covering around the plurality of memory dies with the first molding material having excellent thermal conductivity, heat generated from the plurality of memory dies may be efficiently dissipated to the outside, and by covering around the first molding material with the second molding material having excellent mechanical properties, reliability during the singulation process may be improved.

Dummy structures thermally connected to the molding material of a memory die package, or to the heat dissipation structure, may be disposed in image sensor packages, such that heat generated from the image sensor package may be efficiently released to the outside.

The redistribution structure may include alignment marks for alignment between the plurality of memory dies and the redistribution structure, and alignment marks for alignment between the redistribution structure and the image sensor package. Accordingly, alignment between the logic die within the image sensor package and the plurality of memory dies, each having a size in the horizontal direction that is relatively smaller than the size in the horizontal direction of the logic die, may be accurately achieved, and electrical paths therebetween may be accurately formed.

### BRIEF DESCRIPTION OF THE DRAWINGS

FIG. 1 is a block diagram illustrating an image sensor according to an embodiment.

FIG. 2 is a cross-sectional view showing an image sensor of an embodiment.

FIG. 3 is a cross-sectional view showing an image sensor of an embodiment.

FIG. 4 is a cross-sectional view showing an enlarged region R of the image sensor of FIG. 2.

FIG. 5 is a cross-sectional view showing a heat dissipation path in the image sensor of FIG. 2.

FIG. 6A and 6B are plan views showing the image sensor of embodiments.

FIG. 7A to 7F are plan views showing the alignment marks according to embodiments.

FIGS. 8 to 20 are drawings for illustrating a method of manufacturing memory packages according to an embodiment.

FIG. 21 is a cross-sectional view showing an image sensor of an embodiment.

FIG. 22 is a cross-sectional view showing a heat dissipation path in the image sensor of FIG. 21.

FIGS. 23 to 26 are cross-sectional views for illustrating a method of manufacturing memory packages according to an embodiment.

FIG. 27 is a cross-sectional view showing an image sensor according to an embodiment.

FIG. 28 is a cross-sectional view showing a heat dissipation path in the image sensor of FIG. 21.

FIGS. 29 to 32 are cross-sectional views for explaining a method of manufacturing memory packages according to an embodiment.

FIGS. 33 to 39 are drawings for explaining a method of manufacturing an image sensor by bonding a wafer including memory packages of an embodiment and a wafer including an image sensor package of an embodiment.

### DETAILED DESCRIPTION OF THE EMBODIMENTS

Hereinafter, examples of the present disclosure will be described in detail with reference to the accompanying drawings so that those having ordinary skill in the art to which the present disclosure pertains may easily carry out the present disclosure. This disclosure may be implemented in various different forms and is not limited to the examples described herein.

In the drawings, portions not related to the description have been omitted to clearly explain the present disclosure, and the same reference numerals have been assigned to the same or similar components throughout the specification.

In addition, the sizes and thicknesses of each component shown in the drawings are illustrated arbitrarily for convenience of explanation, and the present disclosure is not necessarily limited to those illustrated unless expressly indicated.

In the entire specification, when a portion is described as being "connected" to another portion, this includes not only the case where they are "directly connected" but also where they are "indirectly connected" with another member interposed therebetween. In addition, when any portion is said to include a certain component, this means that, unless specifically stated otherwise, it does not exclude other components but may include other components.

In addition, when a portion such as a layer, film, region, or plate is described as being "on" or "above" another portion, this not only includes the case where it is "directly on" the other portion but also includes cases where another portion is interposed therebetween. Conversely, when it is stated that any portion is "directly on" another portion, it means that there is no other portion in between. In addition, stating that it is "on" or "on top of" a reference portion means being positioned above or below the reference portion, and does not necessarily mean being positioned "on" or "on top of" in the direction opposite to gravity.

In addition, throughout the specification, the term "on a plane" refers to viewing the relevant portion from above, and the term "on a cross-section" refers to viewing a cross-section of the relevant portion that is vertically cut from the side.

Hereinafter, with reference to the drawings, an embodiment image sensor 10, 10A, 10B, and 10C, and a method of manufacturing the image sensor 10 will be described.

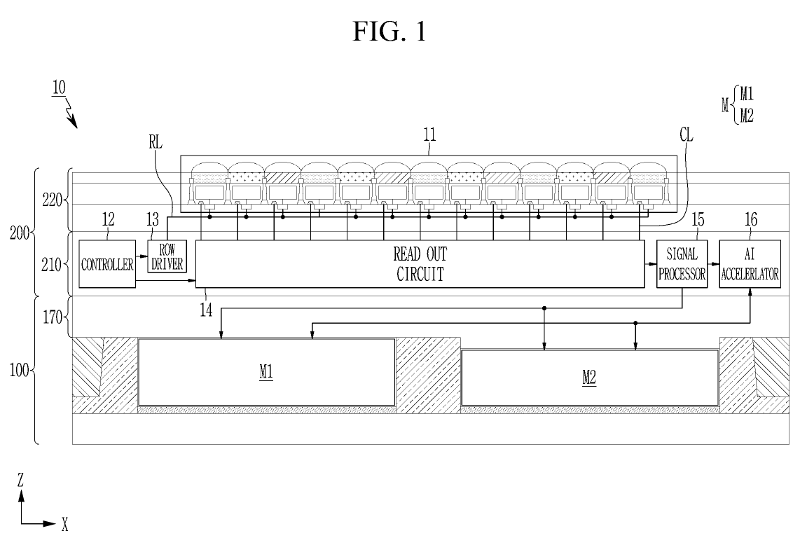

FIG. 1 is a block diagram showing an image sensor 10 of an embodiment. FIG. 1 is a diagram showing a block diagram of the image sensor 10 at one cross-section of the image sensor 10.

Referring to FIG. 1, the image sensor 10 may include a memory package 100 (or first semiconductor package 100) and an image sensor package 200 (or second semiconductor package 200) on the memory package 100. The memory package 100 may include memory dies M and a redistribution structure 170. The image sensor package 200 may include a logic die 210 and an image sensor die 220 on the logic die 210.

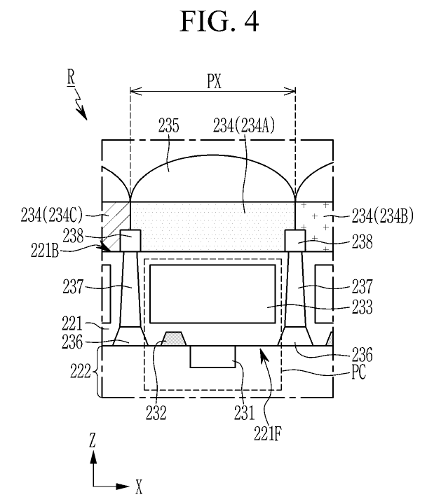

The image sensor die 220 may include a pixel array 11. The pixel array 11 may include pixels PX arranged in rows (X direction) and columns (Y direction, which is perpendicular to both the X direction and the Z direction) on a two-dimensional plane. For each pixel PX of the pixels PX, reference may be made to FIG. 4. Referring to FIG. 4, each pixel PX among the pixels PX may include a micro lens 235, a color filter 234, a photoelectric conversion element 233, and a pixel circuit PC.

Light from the subject is collected at the micro lens 235, and the collected light may be incident on the color filter 234. The color filter 234 may detect and separate light of a specific spectral region among the light that has passed through the micro lens 235, and may transmit the separated light. The light having passed through the color filter 234 may be incident on the photoelectric conversion element 233.

The photoelectric conversion element 233 may detect light transmitted through the color filter 234 and convert the detected light into photocharge. In an embodiment, the photoelectric conversion element 233 may include a photodiode. In an embodiment, the photodiode may be a pn junction type photodiode.

The pixel circuit PC may include a photoelectric conversion circuit and a reading circuit. The photoelectric conversion circuit may include at least one of a photoelectric conversion element 233, a transfer transistor 231, and a floating diffusion 232. The transfer transistor 231 may transfer photocharge converted in the photoelectric conversion element 233 to the floating diffusion 232. The floating diffusion 232 may temporarily accumulate an optical signal transmitted through the transfer transistor 231.

The reading circuit may read the photocharge accumulated in the floating diffusion 232, convert the read photocharge into a pixel signal, and output it to the read-out circuit 14. The reading circuit may include at least one of a transfer transistor, an amplification transistor, a selection transistor, a reset transistor, and a switching transistor.

The pixel array 11 of the image sensor die 220 may be electrically connected to the logic die 210 by the row lines RL and the column lines CL. The row lines RL extend in a row direction, and each row line RL among the row lines RL may be electrically connected to pixels PX arranged in the same row. The column lines CL extend in a column direction, and each column line CL among the column lines CL may be electrically connected to pixels PX arranged in the same column.

The logic die 210 may include a controller 12, a row driver 13, a read-out circuit 14, a signal processing portion 15, and an AI accelerator 16 (or AI processor 16). The controller 12 may control the timing of the row driver 13 and the read-out circuit 14. The controller 12 may generate a clock signal or a control signal serving as a reference for the operations of the row driver 13 and the read-out circuit 14, and may transmit the clock signal or the control signal to the row driver 13 and the read-out circuit 14.

The row driver 13 may generate control signals for driving the pixel array 11. Control signals for driving the pixel array 11 generated by the row driver 13 may be transmitted to each pixel PX of the pixel array 11 through the row lines RL. The row driver 13 may select desired row lines RL and may sequentially transmit control signals for driving the pixel array 11 to the selected row lines RL. The control signals generated by the row driver 13 may be transmitted to the pixels PX arranged within the same row on a row basis. The row driver 13 may control the pixels PX arranged in the same row on a row basis to sense light. The row driver 13 may control the pixel PX to output a pixel signal. The pixel signal output from the pixel PX may be transmitted to the read-out circuit 14 through the column line CL.

The read-out circuit 14 processes the pixel signal delivered through the column line CL from the pixel PX, and may read out the pixel signal. The processing of the pixel signal may be performed in units of columns of pixels PX. In an embodiment, the read-out circuit 14 may include an Analog to digital converter (ADC) circuit, a Correlated Double Sampling (CDS) circuit, a counter circuit, and a data bus. The ADC circuit may convert a pixel signal delivered from the pixel PX through the column line CL into a pixel value, which is digital data. The CDS circuit may compare the pixel signal delivered from the pixel PX through the column line CL with a ramp signal, and may output a comparison signal corresponding to the comparison result. The CDS circuit may sample and hold the pixel signal delivered from the pixel PX according to a CDS scheme, and may output a comparison signal by performing double sampling of a specific noise level and an image signal level, and generating a signal corresponding to the difference therebetween. In an embodiment, the CDS circuit may include a comparator. The data bus may temporarily store pixel values generated in the ADC circuit and may output them as image data. The image data output from the data bus may be transmitted to the signal processing portion 15.

The signal processing portion 15 may perform at least one of noise removal, gain adjustment, waveform shaping processing, interpolation processing, white balance processing, gamma processing, edge enhancement processing, and binning on image data delivered from the data bus. The signal processing portion 15 may be an image signal processor (ISP). The image data corrected and processed in the signal processing portion 15 may be transmitted to the memory dies M1 and M2 or the AI accelerator 16.

The AI accelerator 16 may analyze the image data, which has been corrected and processed by the signal processing portion 15, in real time, and may perform learning or inference. The AI accelerator 16 may perform tasks including object recognition, face recognition, gesture recognition, and image classification on image data. The AI accelerator 16 may execute a deep learning algorithm. In an embodiment, the AI accelerator 16 may be integrated into the signal processing portion 15. In an embodiment, the AI accelerator 16 may be edge artificial intelligence embedded in the image sensor.

The memory dies M may be disposed within the memory package 100. In FIG. 1, although two memory dies M1 and M2 are illustrated, the present invention is not limited thereto, and the memory dies may be N memory dies. Here, N may be a natural number of 2 or more. The memory dies M may be electrically connected to the logic die 210. A redistribution structure 170 may be disposed between the memory dies M and the logic die 210. The memory dies M may be electrically connected to the logic die 210 through redistribution lines and redistribution vias in the redistribution structure 170. The memory dies M may store image data corrected and processed in the signal processing portion 15, store image data on which learning or inference is performed in the AI accelerator 16, or transmit image data stored in the memory dies M to the AI accelerator 16. In an embodiment, the memory dies M may include a dynamic random access memory (DRAM), static random access memory (SRAM), or flash memory.

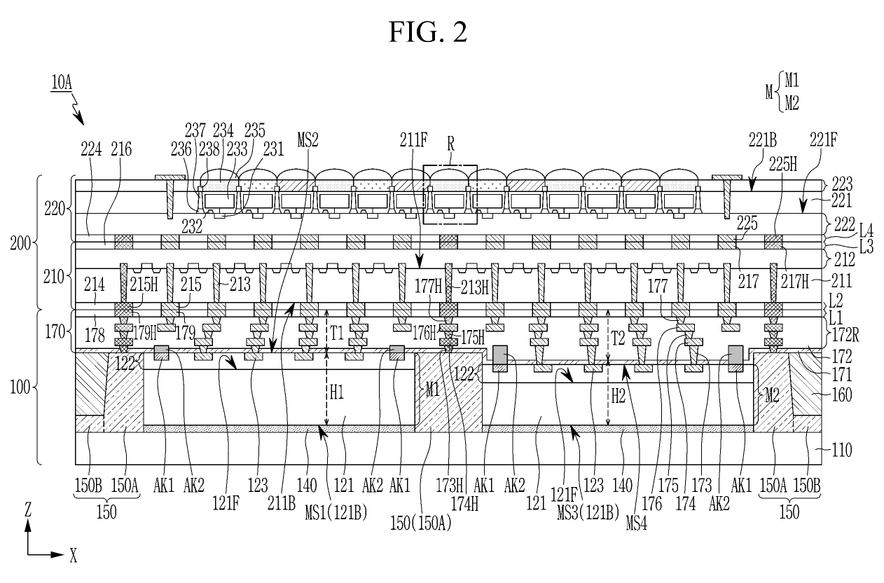

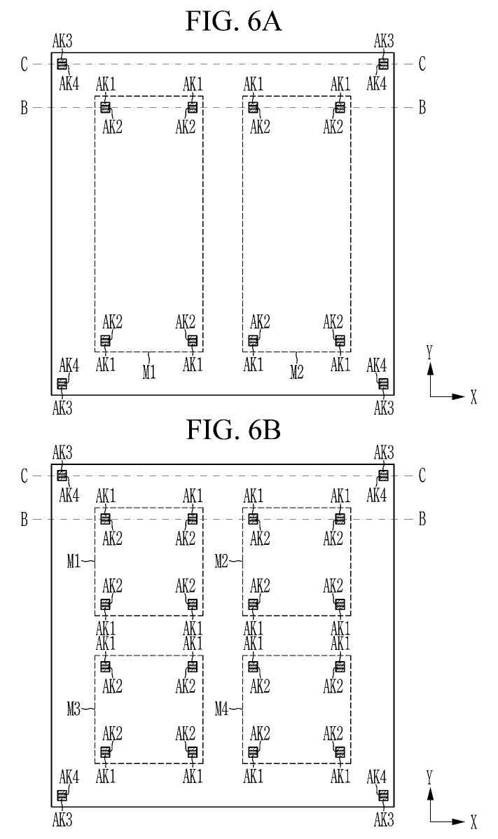

FIG. 2 is a cross-sectional view showing an image sensor 10A of an embodiment. FIG. 2 is a cross-sectional view showing the image sensor 10A of FIGS. 6A and 6B cut along line B-B.

Referring to FIG. 2, the image sensor 10A may include the memory package 100 and the image sensor package 200. In an embodiment, the image sensor 10A may be implemented in a System In Package (SIP) configuration. The image sensor 10A according to the present disclosure is an implementation of a plurality of semiconductor dies as a single semiconductor package, and may operate as a single chip. In an embodiment, the image sensor 10A may include a three-dimensional integrated circuit (3DIC). In an embodiment, the image sensor 10A may be a semiconductor package manufactured based on fan out wafer level package (FOWLP) or fan out panel level package (FOPLP) technology.

The memory package 100 and the image sensor package 200 may be bonded to each other by hybrid bonding to constitute the image sensor 10A. In order to stack an image sensor package 200 including a logic die 210 and an image sensor die 220 having a high input/output (I/O) density on a memory package 100 including memory dies M having a high I/O density, a hybrid bonding process may be applied to the bonding between the memory package 100 and the image sensor package 200. Hybrid bonding is bonding two devices by fusing the same materials of the two devices using the bonding properties of the same material. Here, the hybrid refers to the bonding of two different types, for example, bonding two devices by bonding between metal-metal of a first type and nonmetal-nonmetal of a second type. A CSP packaging method may be applied to the manufacturing of the image sensor 10A. In the CSP packaging method, a wafer (panel) on which image sensor packages are formed and a wafer (panel) on which memory packages are formed are hybrid-bonded to form a wafer (panel) to wafer (panel) bonding structure, and then the wafer (panel) to wafer (panel) bonding structure is singulated to manufacture image sensors.

The memory package 100 may include a support substrate 110, memory dies M, adhesive members 140, a first molding material 150, a second molding material 160, and a redistribution structure 170.

The support substrate 110 (or dummy die 110) may support the memory dies M. In an embodiment, no wirings for signal routing or power supply are formed in the support substrate 110. The support substrate 110 may serve to support the memory dies M and dissipate heat generated from the image sensor 10A. In an embodiment, the support substrate 110 may include a heat dissipation structure. In an embodiment, the support substrate 110 may include a heat slug, a heat sink, or a heat spreader. In an embodiment, the support substrate 110 may include a conductive material having high thermal conductivity. In an embodiment, the support substrate 110 may include at least one of copper, aluminum, silver, tin, gold, nickel, lead, titanium, and alloys thereof. In an embodiment, the support substrate 110 may include a silicon-based material such as silicon oxide, another material such as aluminum oxide, or any combination of these materials. The support substrate 110 may be thermally connected to the first molding material 150. In an embodiment, the support substrate 110 may contact the first molding material 150. The term “contact,” as used herein, refers to a direct connection (i.e., physical touching) unless the context indicates otherwise.

Memory dies M may be disposed on the support substrate 110. The memory dies M may be arranged side by side. The memory dies M may penetrate the first molding material 150. The side surfaces of each memory die M of the memory dies M may be in contact with the first molding material 150. In FIG. 1, the memory package 100 including two memory dies (M1 and M2) is disclosed, but is not limited thereto, and a memory package 100 including a greater number of memory dies M may be included in the scope of the present disclosure. For example, the memory package 100 may include 4, 8, 12, 16, or 20 memory dies M.

Each memory die M among the memory dies M may include a die base 121 and a front structure 122. In an embodiment, the memory dies M may include DRAM, SRAM, or flash memory. In an embodiment, the memory dies M may include different types of memories. For example, some of the memory dies M may be implemented as DRAM, some of the memory dies M may be implemented as SRAM, and the other may be implemented as flash memory. For example, some of the memory dies M may be implemented as DRAM, and the others may be implemented as SRAM. The present disclosure is not limited thereto. The memory devices M may include various different types of memories having different heights. In some embodiments, the memory dies M may include the same type of memories having different heights. The heights may be defined with reference to an upper surface of the support substrate 110.

The die base 121 may include a front side 121F facing the redistribution structure 170 and a back side 121B opposite to the front side 121F. The die base 121 may be a die formed from a wafer. In an embodiment, the die base 121 may include silicon or another semiconductor material.

The front structure 122 may be disposed on the front side 121F of the die base 121. The front structure 122 may include a device layer and a wiring layer. The device layer may be disposed on the front side 121F of the die base 121. The device layer may include an integrated circuit structure having integrated circuit regions. In an embodiment, the integrated circuit structure may include at least one of an active device and a passive device. In an embodiment, the integrated circuit structure may include a gate structure, a source region, and a drain region. In an embodiment, the integrated circuit structure may include at least one of a transistor, a diode, a capacitor, an inductor, and a resistor. The wiring layer may be disposed on the device layer. The wiring layer may include wiring lines for signals, wiring lines for power, contact plugs, and an inter metal dielectric (IMD). The wiring layer may include connection pads 123 and first alignment marks AK1. Each of the connection pads 123 may contact and be electrically connected to a corresponding first redistribution via 173 among the first redistribution vias 173 of the redistribution structure 170. Each of the first alignment marks AK1 may be aligned with a corresponding second alignment mark AK2 among the second alignment marks AK2 of the redistribution structure 170. In an embodiment, the connection pads 123 and the first alignment marks AK1 may each include at least one of aluminum, silver, tin, gold, nickel, lead, titanium, and alloys thereof. The memory dies M, even if the memory dies are formed on a single wafer, may have heights different from each other in a vertical direction as a result of accumulation of the topography of each layer within each memory die M. Due to such a height difference, the bonding surface of a wafer (panel) including memory dies having different heights may have a surface roughness value unsuitable for performing hybrid bonding.

The first memory die M1 among the memory dies M may include a first surface MS1 contacting the support substrate 110, and a second surface MS2 being opposite to the first surface MS1 and contacting the redistribution structure 170. The first memory die M1 may have a first height H1 between the first surface MS1 and the second surface MS2. The second memory die M2 among the memory dies M may be disposed beside the first memory die M1. The second memory die M2 among the memory dies M may include a third surface MS3 contacting the support substrate 110, and a fourth surface MS4 that is opposite to the third surface MS3 and contacts the redistribution structure 170. The second memory die M2 may have a second height H2 between the third surface MS3 and the fourth surface MS4. The second height H2 may be smaller than the first height H1. The first memory die M1 has an upper surface coplanar with an upper surface of the first molding material 150. The second memory die M2 has an upper surface lower than the upper surface of the first molding material 150.

The adhesive member 140 may be disposed between the support substrate 110 and each memory die M among the memory dies M. The adhesive member 140 may attach each memory die M of the memory dies M to the support substrate 110.

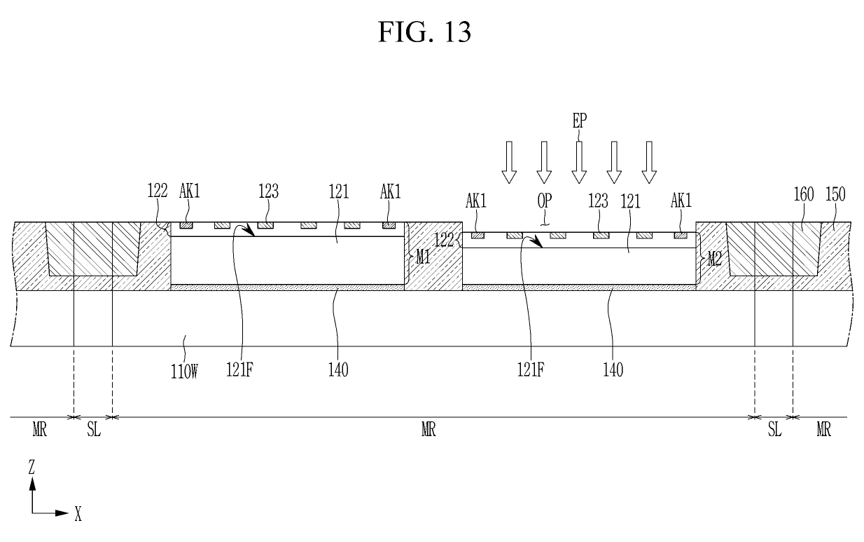

The first molding material 150 may surround the memory dies M and may be disposed in a space between the support substrate 110 and the redistribution structure 170. The first molding material 150 may cover a side portion (i.e., a sidewall) of each memory die M among the memory dies M. The first molding material 150 may include openings OP (see FIG. 13). Each of openings OP of the first molding material 150 may have the corresponding memory die M among the memory dies M disposed therein. The upper surface of the memory die M having the greatest height in a vertical direction among the memory dies M may be on a same plane in the vertical direction (Z direction) as the upper surface of the first molding material 150 and the upper surface of the second molding material 160. Each memory die M among the remaining memory dies M except for the memory die M having the greatest height in a vertical direction (Z direction) among the memory dies M, may have its upper surface exposed within a corresponding opening OP among the openings OP. On the upper surface of each memory die M among the remaining memory dies M except for the memory die M having the greatest height in the vertical direction (Z direction), a corresponding opening OP may be filled by a dielectric 172 of the redistribution structure 170.

The first molding material 150 may include a first portion 150A and a second portion 150B. The first portion 150A may cover the side portions of each memory die M among the memory dies M between the support substrate 110 and the redistribution structure 170. The second portion 150B may extend in a horizontal direction (X direction and Y direction) between the support substrate 110 and the second molding material 160, and may be exposed to the outside at the side portions of the memory package 100.

The first molding material 150 may be thermally connected to the support substrate 110, the memory dies M, the dummy structures 173H, 174H, 175H, 176H, 177H, and 179H of the redistribution structure 170, the dummy structures 213H, 215H, and 217H of the logic die 210, and the dummy structure 225H of the image sensor die 220. The first molding material 150 may include a material having high thermal conductivity. In an embodiment, the thermal conductivity of the first molding material 150 may be at least 10 W/m∙K.

The second molding material 160 may surround the first portion 150A of the first molding material 150 between the second portion 150B of the first molding material 150 and the redistribution structure. The second molding material 160 may be exposed to the outside at the side portions of the memory package 100. The second molding material 160 may include a material having excellent mechanical strength sufficient to withstand the singulation process.

The redistribution structure 170 may be disposed on the memory dies M, the first molding material 150, and the second molding material 160. The redistribution structure 170 may include an etch stop layer 171, a redistribution layer 172R, and a first bonding layer L1.

The etch stop layer 171 may be disposed between the memory dies M and the dielectric 172 of the redistribution structure 170, between the first molding material 150 and the dielectric 172 of the redistribution structure 170, and between the second molding material 160 and the dielectric 172 of the redistribution structure 170. The etch stop layer 171 may extend conformally along upper surfaces of the memory dies M, an upper surface of the first molding material 150, inner surfaces of openings of the first molding material 150, and an upper surface of the second molding material 160. The etch stop layer 171 may be penetrated by the first redistribution vias 173, and may be penetrated by the second alignment marks AK2.

The redistribution layer 172R may include the dielectric 172, and first redistribution vias 173, first redistribution lines 174, second redistribution vias 175, second redistribution lines 176, third redistribution vias 177, first dummy vias 173H, first dummy lines 174H, second dummy vias 175H, second dummy lines 176H, and third dummy vias 177H disposed in the dielectric 172. In another example, a redistribution layer 172R including fewer or greater numbers of redistribution lines, redistribution vias, dummy lines, and dummy vias may be included in the scope of the present disclosure. As used herein, the term “dummy” is used to refer to a component that has the same or similar structure and shape as other components but does not have a substantial electrical function and exists only as a pattern for forming a heat flow path for heat dissipation in the device.

The dielectric 172 may protect and insulate the first redistribution vias 173, the first redistribution lines 174, the second redistribution vias 175, the second redistribution lines 176, the third redistribution vias 177, the first dummy vias 173H, the first dummy lines 174H, the second dummy vias 175H, the second dummy lines 176H, the third dummy vias 177H, and the second alignment marks AK2. An upper surface of the dielectric 172 may be provided with the first bonding layer L1. The etch stop layer 171 may be disposed on the lower surface of the dielectric 172. The first redistribution vias 173, first redistribution lines 174, second redistribution vias 175, second redistribution lines 176, and third redistribution vias 177 are sequentially arranged from the bottom, and may form signal, ground, and power routing paths. The first dummy vias 173H, the first dummy lines 174H, the second dummy vias 175H, the second dummy lines 176H, and the third dummy vias 177H are sequentially arranged from the bottom and may form heat transfer paths. The first dummy vias 173H, the first dummy lines 174H, the second dummy vias 175H, the second dummy lines 176H, and the third dummy vias 177H may be thermally connected to the first molding material 150, and to the first dummy bonding pads 179H. The first dummy vias 173H, the first dummy lines 174H, the second dummy vias 175H, the second dummy lines 176H, and the third dummy vias 177H may be electrically separated from other configurations. The first redistribution lines 174, the second redistribution lines 176, the first dummy vias 173H, the first dummy lines 174H, and the second dummy lines 176H may extend in a horizontal direction within the dielectric 172. The first redistribution vias 173, the second redistribution vias 175, the third redistribution vias 177, the first dummy vias 173H, the second dummy vias 175H, and the third dummy vias 177H may extend in a vertical direction within the dielectric 172. In an embodiment, the first redistribution vias 173, the first redistribution lines 174, the second redistribution vias 175, the second redistribution lines 176, the third redistribution vias 177, the first dummy vias 173H, the first dummy lines 174H, the second dummy vias 175H, the second dummy lines 176H, and the third dummy vias 177H may each include at least one of copper, aluminum, silver, tin, gold, nickel, lead, titanium, and alloys thereof. The dielectric 172 is disposed on the fourth surface MS4 of the second memory die M2. A lower surface of the dielectric 172 on the fourth surface MS4 of the second memory die M2 is lower than an upper surface of the first molding material 150. An upper surface of the first memory die M1 is coplanar with the upper surface of the first molding material 150.

Each of the second alignment marks AK2 may be aligned with a corresponding first alignment mark AK1 among the first alignment marks AK1 of the memory dies M. In an embodiment, the second alignment marks AK2 may include at least one of copper, aluminum, silver, tin, gold, nickel, lead, titanium, and alloys thereof.

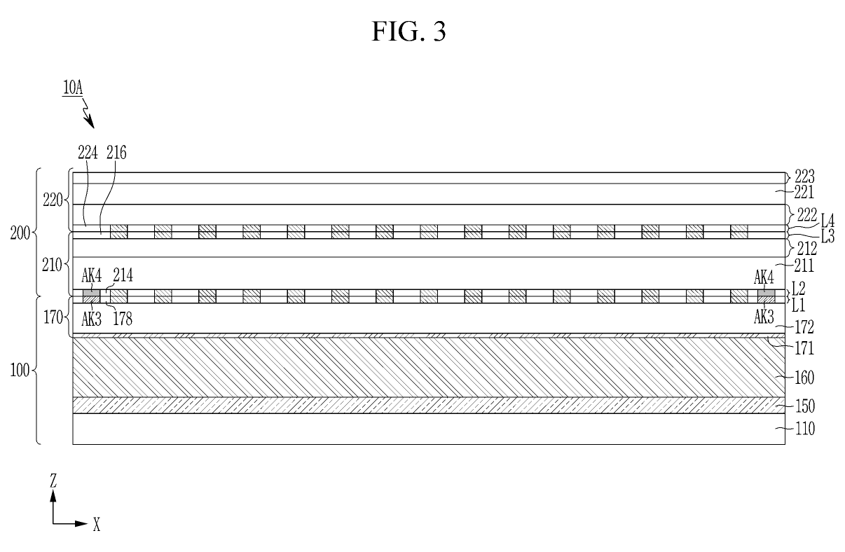

The first bonding layer L1 may be disposed on the redistribution layer 172R. The first bonding layer L1 may include a first bonding dielectric layer 178, first bonding pads 179, first dummy bonding pads 179H, and third alignment marks AK3 (see FIG. 3).

The first bonding dielectric layer 178 may be disposed on the redistribution layer 172R. The first bonding dielectric layer 178 may be disposed between the redistribution layer 172R and the second bonding dielectric layer 214 of the logic die 210. The first bonding dielectric layer 178 may be bonded to the second bonding dielectric layer 214 of the logic die 210 by dielectric- to-dielectric bonding of hybrid bonding. For example, the first bonding dielectric layer 178 may be directly bonded to the second bonding dielectric layer 214 in hybrid bonding. The first bonding dielectric layer 178 may surround the first bonding pads 179, the first dummy bonding pads 179H, and the third alignment marks AK3 (see FIG. 3). In an embodiment, the first bonding dielectric layer 178 may include a silicon compound. In an embodiment, the first bonding dielectric layer 178 may include silicon oxide or silicon nitride. In an embodiment, the first bonding dielectric layer 178 may include SiO2, SiN, or SiCN. In an embodiment, the first bonding dielectric layer 178 may have a thickness in the range of about 0.1 μm to about 8 μm in a vertical direction (Z direction). Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

The first bonding pads 179 may penetrate the first bonding dielectric layer 178. Each of the first bonding pads 179 may be disposed between a corresponding third redistribution via 177 among the third redistribution vias 177 and a corresponding second bonding pad 215 among the second bonding pads 215 of the logic die 210. Each of the first bonding pads 179 may electrically connect a corresponding second bonding pad 215 among the second bonding pads 215 of the logic die 210 to a corresponding third redistribution via 177 among the third redistribution vias 177. Each of the first bonding pads 179 may be bonded to a corresponding second bonding pad 215 among the second bonding pads 215 of the logic die 210 by performing metal-to-metal bonding in hybrid bonding. For example, the bonding pads 179 may be directly bonded to the second bonding pads 215 in hybrid bonding. By such metal-to-metal bonding in the hybrid bonding, electrical connection may be made between the memory package 100 and the image sensor package 200.

The first dummy bonding pads 179H may penetrate the first bonding dielectric layer 178. The first dummy bonding pads 179H may be thermally connected to the second dummy bonding pads 215H of the second bonding layer L2, and to the third dummy vias 177H of the redistribution structure 170. The first dummy bonding pads 179H may be electrically separated from other components within the image sensor 10A.

A bonding surface of each of the first bonding pads 179 and a bonding surface of each of the first dummy bonding pads 179H may be on the same plane as a bonding surface of the first bonding dielectric layer 178. Side portions of each of the first bonding pads 179 and side portions of each of the first dummy bonding pads 179H may be surrounded by the first bonding dielectric layer 178. In an embodiment, the first bonding pads 179 and the first dummy bonding pads 179H may each have a width in a range of about 0.01 μm to about 30 μm in the horizontal direction (X direction and Y direction). In an embodiment, the first bonding pads 179 and the first dummy bonding pads 179H may each have a thickness in a range of about 0.1 μm to about 8 μm in a vertical direction (Z direction). In an embodiment, the first bonding pads 179 and the first dummy bonding pads 179H may each include copper or a copper alloy.

The third alignment marks AK3 are illustrated in FIG. 3. FIG. 3 is a cross-sectional view showing an image sensor 10A according to an embodiment. FIG. 3 is a cross-sectional view showing the image sensor 10A of FIGS. 6A and 6B cut along line C-C.

The third alignment marks AK3 may penetrate the first bonding dielectric layer 178. The third alignment marks AK3 may be dummy patterns. The third alignment marks AK3 may be electrically isolated from other configurations within the image sensor 10A. The third alignment marks AK3 may include the same material as the first bonding pads 179. In an embodiment, the third alignment marks AK3 may include copper or a copper alloy.

Referring to FIG. 2, the redistribution structure 170 may have a structure that compensates for the height differences of the memory dies M, so that the bonding surface of the wafer (panel) including the memory dies M having different heights has a surface roughness value suitable for performing hybrid bonding. The redistribution structure 170 is in contact with upper surface of each of the memory dies M, and the redistribution structure 170 may have a thickness profile having two different thickness values in a vertical direction (Z direction) on each of the memory dies M. The redistribution structure 170 may have a first thickness T1 on the first memory die M1. The redistribution structure 170 may have a second thickness T2 on the second memory die M2. The second thickness T2 may be greater than the first thickness T1. In an embodiment, the sum of the first thickness T1 and the first height H1 may be substantially equal to the sum of the second thickness T2 and the second height H2. Terms such as “same,” “equal,” “planar,” or “coplanar,” as used herein encompass near identicality including variations that may occur, for example, due to manufacturing processes. The term “substantially” may be used herein to emphasize this meaning, unless the context or other statements indicate otherwise.

The image sensor package 200 may include the logic die 210 and the image sensor die 220. In an embodiment, the image sensor package 200 may be implemented in a SIP configuration. In an embodiment, the image sensor package 200 may include a 3DIC. In an embodiment, the image sensor package 200 may be a semiconductor package manufactured based on a FOWLP or FOPLP technology. The logic die 210 and the image sensor die 220 may be bonded to each other by hybrid bonding to constitute the image sensor package 200.

The logic die 210 may include a die base 211, a front structure 212, through silicon vias 213, dummy through silicon vias 213H, a second bonding layer L2, and a third bonding layer L3. The die base 211 may include a front side 211F and a back side 211B which is an opposite surface to the front side 211F. The die base 211 may be a die formed from a wafer. In an embodiment, the die base 211 may include silicon or another semiconductor material.

The front structure 212 may be disposed on the front side 211F of the die base 211. The die base 211 may include a device layer and a wiring layer. The device layer may be disposed on the front side 211F of the die base 211. The device layer may include an integrated circuit structure having integrated circuit regions. In an embodiment, the integrated circuit structure may include the controller 12, the row driver 13, the read-out circuit 14, the signal processing portion 15, and the AI accelerator 16 as described with reference to FIG. 1. In an embodiment, the integrated circuit structure may include at least one of an active device and a passive device. In an embodiment, the integrated circuit structure may include a gate structure, a source region, and a drain region. In an embodiment, the integrated circuit structure may include at least one of a transistor, diode, capacitor, inductor, and resistor. The wiring layer may be disposed on the device layer. The wiring layer may include wiring lines for signals, wiring lines for power, contact plugs, and an IMD.

Through silicon vias 213 may extend from the wiring layer of the front structure 212, through the die base 211, to the back side 211B of the die base 211. A first end of each of the through silicon vias 213 is connected to a corresponding second bonding pad 215 among the second bonding pads 215 of the second bonding layer L2, and a second end of each of the through silicon vias 213 may be connected to a wiring line of the wiring layer. The second end may be the opposite end of the first end.

Dummy through silicon vias 213H may extend from the wiring layer of the front structure 212, through the die base 211, to the back side 211B of the die base 211. The dummy through silicon vias 213H may be thermally connected to the second dummy bonding pads 215H of the second bonding layer L2, and to the third dummy bonding pads 217H of the third bonding layer L3. The dummy through silicon vias 213H may be electrically separated from other configurations within the image sensor 10A. For example, the dummy through silicon vias 213H may extend from the wiring layer of the front structure 212 without being connected to wiring lines for signals, wiring lines for power, or contact plugs of the wiring layer. In an embodiment, the dummy through silicon vias 213H may extend from dummy wiring layers in the front structure 212 to form a heat flow path.

In an embodiment, the through silicon vias 213 and the dummy through silicon vias 213H may each include at least one of tungsten, aluminum, copper, and alloys thereof. Barrier layers may be formed around each of the through silicon vias 213 and the dummy through silicon vias 213H. The barrier layer may serve to prevent the silicon of the die base 211 or the dielectric of the front structure 212 from coming into contact with the through silicon vias 213 or the dummy through silicon vias 213H.

The second bonding layer L2 may be disposed on the back side 211B of the die base 211. The second bonding layer L2 may include a second bonding dielectric layer 214, second bonding pads 215, second dummy bonding pads 215H, and fourth alignment marks AK4 (see FIG. 3).

The second bonding dielectric layer 214 may be disposed on the back side 211B of the die base 211. The second bonding dielectric layer 214 may be disposed between the die base 211 and the first bonding dielectric layer 178 of the redistribution structure 170. The second bonding dielectric layer 214 may be bonded to the first bonding dielectric layer 178 of the redistribution structure 170 by dielectric-to-dielectric bonding in hybrid bonding. The second bonding dielectric layer 214 may surround the second bonding pads 215, the second dummy bonding pads 215H, and the fourth alignment marks AK4 (see FIG. 3). In an embodiment, the second bonding dielectric layer 214 may include a silicon compound. In an embodiment, the second bonding dielectric layer 214 may include silicon oxide or silicon nitride. In an embodiment, the second bonding dielectric layer 214 may include SiO2, SiN, or SiCN. In an embodiment, the second bonding dielectric layer 214 may have a thickness in a range of about 0.1 μm to about 8 μm in a vertical direction (Z direction).

The second bonding pads 215 may penetrate the second bonding dielectric layer 214. Each of the second bonding pads 215 may be disposed between a corresponding through silicon via 213 among the through silicon vias 213 and a corresponding first bonding pad 179 among the first bonding pads 179 of the first bonding layer L1. Each of the second bonding pads 215 may electrically connect a corresponding first bonding pad 179 among the first bonding pads 179 of the first bonding layer L1 to a corresponding through silicon via 213 among the through silicon vias 213. Each of the second bonding pads 215 may be bonded to a corresponding first bonding pad 179 among the first bonding pads 179 of the first bonding layer L1 by metal-to-metal bonding in hybrid bonding. By such metal-to-metal bonding in the hybrid bonding, electrical connection may be made between the memory package 100 and the image sensor package 200.

The second dummy bonding pads 215H may penetrate the second bonding dielectric layer 214. The second dummy bonding pads 215H may be thermally connected to the first dummy bonding pads 179H of the first bonding layer L1 and to the dummy through silicon vias 213H. The second dummy bonding pads 215H may be electrically separated from other components within the image sensor 10A.

A bonding surface of each of the second bonding pads 215 and a bonding surface of each of the second dummy bonding pads 215H may be on a same plane as a bonding surface of the second bonding dielectric layer 214. Side portions of each of the second bonding pads 215 and side portions of each of the second dummy bonding pads 215H may be surrounded by the second bonding dielectric layer 214. In an embodiment, the second bonding pads 215 and the second dummy bonding pads 215H may each have a width ranging from about 0.01 μm to about 30 μm in the horizontal direction (X direction and Y direction). In an embodiment, the second bonding pads 215 and the second dummy bonding pads 215H may each have a thickness in the range of about 0.1 μm to about 8 μm in the vertical direction (Z direction). In an embodiment, the second bonding pads 215 and the second dummy bonding pads 215H may each include copper or a copper alloy.

The fourth alignment marks AK4 are illustrated in FIG. 3. The fourth alignment marks AK4 may penetrate the second bonding dielectric layer 214. The fourth alignment marks AK4 may be dummy patterns. The fourth alignment marks AK4 may be electrically separated from other components within the image sensor 10A. The fourth alignment marks AK4 may include the same material as the second bonding pads 215. In an embodiment, the fourth alignment marks AK4 may include copper or a copper alloy.

Referring to FIG. 2, the third bonding layer L3 may be disposed on the front structure 212. The third bonding layer L3 may include a third bonding dielectric layer 216, third bonding pads 217, and third dummy bonding pads 217H.

The third bonding dielectric layer 216 may be disposed on the front structure 212. The third bonding dielectric layer 216 may be disposed between the front structure 212 and the fourth bonding dielectric layer 224 of the image sensor die 220. The third bonding dielectric layer 216 may be bonded to the fourth bonding dielectric layer 224 of the image sensor die 220 by dielectric-to-dielectric bonding in hybrid bonding. The third bonding dielectric layer 216 may surround the third bonding pads 217 and the third dummy bonding pads 217H. In an embodiment, the third bonding dielectric layer 216 may include a silicon compound. In an embodiment, the third bonding dielectric layer 216 may include silicon oxide or silicon nitride. In an embodiment, the third bonding dielectric layer 216 may include SiO2, SiN, or SiCN. In an embodiment, the third bonding dielectric layer 216 may have a thickness in a range of about 0.1 μm to about 8 μm in a vertical direction (Z direction).

The third bonding pads 217 may penetrate the third bonding dielectric layer 216. Each of the third bonding pads 217 may be disposed between a wiring layer of the front structure 212 and a corresponding fourth bonding pad 225 among the fourth bonding pads 225 of the fourth bonding layer L4 of the image sensor die 220. Each of the third bonding pads 217 may electrically connect a corresponding fourth bonding pad 225 among the fourth bonding pads 225 of the fourth bonding layer L4 to the wiring layer of the front structure 212. Each of the third bonding pads 217 may be bonded to a corresponding fourth bonding pad 225 among the fourth bonding pads 225 of the fourth bonding layer L4 by metal-to-metal bonding in hybrid bonding. By such metal-to-metal bonding in the hybrid bonding, an electrical connection may be made between the logic die 210 and the image sensor die 220.

The third dummy bonding pads 217H may penetrate the third bonding dielectric layer 216. The third dummy bonding pads 217H may be thermally connected to the fourth dummy bonding pads 225H of the fourth bonding layer L4, and to the dummy through silicon vias 213H. The third dummy bonding pads 217H may be electrically separated from other components within the image sensor 10A.

A bonding surface of each of the third bonding pads 217 and the bonding surface of each of the third dummy bonding pads 217H may be on the same plane as a bonding surface of the third bonding dielectric layer 216. Side portions of each of the third bonding pads 217 and side portions of each of the third dummy bonding pads 217H may be surrounded by the third bonding dielectric layer 216. In an embodiment, the third bonding pads 217 and the third dummy bonding pads 217H may each have a width in a range of about 0.01 μm to about 30 μm in the horizontal direction (X direction and Y direction). In an embodiment, the third bonding pads 217 and the third dummy bonding pads 217H may each have a thickness in a range of about 0.1 μm to about 8 μm in the vertical direction (Z direction). In an embodiment, the third bonding pads 217 and the third dummy bonding pads 217H may each include copper or a copper alloy.

The image sensor die 220 may include a die base 221, a filter layer 223 (i.e., a color filter layer), a micro lens 235, a front structure 222, and a fourth bonding layer L4. The die base 221, filter layer 223, micro lens 235, and front structure 222 may constitute the pixel array 11 (see FIG. 1). One pixel PX of the pixel array 11 is illustrated in FIG. 4. FIG. 4 is a view illustrating an enlarged region R of FIG. 2.

Referring to FIG. 2 and FIG. 4, the die base 221 may include a front side 221F and a back side 221B, which is an opposite surface of the front side 221F. The die base 221 may be a die formed from a wafer. In an embodiment, the die base 221 may include silicon or another semiconductor material. The die base 221 may include floating diffusions 232, photoelectric conversion elements 233, element isolation patterns 236, and pixel separation structures 237.

Each of the floating diffusions 232 may be embedded in the die base 221, and may be connected to corresponding transfer transistors 231 among the transfer transistors 231. The floating diffusion 232 may receive and accumulate an optical signal generated from the photoelectric conversion element 233 via the transfer transistor 231.

Each of the photoelectric conversion elements 233 may be embedded in the die base 221 and may be connected to corresponding transfer transistors 231 among the transfer transistors 231. The photoelectric conversion element 233 may detect light transmitted through the color filter 234, and convert the detected light into photocharge.

The element isolation patterns 236 and the pixel separation structures 237 may define a space of each pixel PX among pixels PX arranged in a plurality of rows and a plurality of columns within the die base 221. The floating diffusions 232, or photoelectric conversion elements 233, may be physically and electrically separated from each other by the element isolation patterns 236, and by the pixel separation structures 237. The element isolation patterns 236 may be embedded in the die base 221, and may define an active region in which a photoelectric conversion circuit constituting the pixel circuit PC is to be formed, and in which a reading circuit constituting the pixel circuit PC is to be formed. The element isolation patterns 236 may be formed by patterning the front side 221F of the die base 221 to form shallow trenches and filling the formed shallow trenches with an insulating material. The pixel separation structures 237 may be formed by patterning the front side 221F of the die base 221 to form deep trenches, forming an insulating layer conformally within the deep trenches, and filling the trenches with a conductive material. In an embodiment, the insulating layer may include at least one of the group consisting of silicon oxide, silicon nitride, silicon oxynitride, hafnium oxide, aluminum oxide, and tantalum oxide. In an embodiment, the conductive material may include at least one of doped polysilicon, metal, metal silicide, metal nitride, and metal-containing layer.

The filter layer 223 may be disposed on the back side 221B of the die base 221. The filter layer 223 may include a grid structure 238 and the color filters 234. The grid structure 238 may define a space of each pixel PX among the pixels PX arranged in a plurality of rows and a plurality of columns within the filter layer 223. The grid structure 238, when viewed in a plan view, may include intersecting linear portions defining spaces accommodating the color filters 234. Each of the intersecting linear portions of the grid structure 238 may extend from a corresponding pixel separation structure 237 among the pixel separation structures 237. The color filters 234 may be disposed in spaces of respective pixels PX defined by the grid structure 238. The color filters 234 may include a first color filter 234A for sensing and separating light in the red spectral region and transmitting it, a second color filter 234B for sensing and separating light in the green spectral region and transmitting it, and a third color filter 234C for sensing and separating light in the blue spectral region and transmitting it.

Micro lenses 235 may be disposed on the filter layer 223. Each of the micro lenses 235 may be disposed on a corresponding color filter 234 among the color filters 234.

The front structure 222 may be disposed on the front side 221F of the die base 221. The front structure 222 may include a device layer and a wiring layer. The device layer may be disposed on the front side 221F of the die base 221. The device layer may include an integrated circuit structure having integrated circuit regions. In an embodiment, the integrated circuit structure may include at least one of a transfer transistor 231, an amplification transistor, a selection transistor, a reset transistor, and a switching transistor. In an embodiment, the integrated circuit structure may include at least one of an active device and a passive device. In an embodiment, the integrated circuit structure may include a gate structure, a source region, and a drain region. In an embodiment, the integrated circuit structure may include at least one of a transistor, a diode, a capacitor, an inductor, and a resistor. The wiring layer may be disposed on the device layer. The wiring layer may include wiring lines for signals, wiring lines for power, contact plugs, and an IMD.

The fourth bonding layer L4 may be disposed on the front structure 222. The fourth bonding layer L4 may include the fourth bonding dielectric layer 224, fourth bonding pads 225, and fourth dummy bonding pads 225H.

The fourth bonding dielectric layer 224 may be disposed on the front structure 222. The fourth bonding dielectric layer 224 may be disposed between the front structure 222 and the third bonding dielectric layer 216 of the logic die 210. The fourth bonding dielectric layer 224 may be bonded to the third bonding dielectric layer 216 of the logic die 210 by dielectric-to-dielectric bonding in hybrid bonding. The fourth bonding dielectric layer 224 may surround the fourth bonding pads 225 and the fourth dummy bonding pads 225H. In an embodiment, the fourth bonding dielectric layer 224 may include a silicon compound. In an embodiment, the fourth bonding dielectric layer 224 may include silicon oxide or silicon nitride. In an embodiment, the fourth bonding dielectric layer 224 may include SiO2, SiN, or SiCN. In an embodiment, the fourth bonding dielectric layer 224 may have a thickness in the range of about 0.1 μm to about 8 μm in the vertical direction (Z direction).

The fourth bonding pads 225 may penetrate the fourth bonding dielectric layer 224. Each of the fourth bonding pads 225 may be disposed between the wiring layer of the front structure 222 and a corresponding third bonding pad 217 among the third bonding pads 217 of the third bonding layer L3 of the logic die 210. Each of the fourth bonding pads 225 may electrically connect a corresponding third bonding pad 217 of the third bonding pads 217 of the third bonding layer L3 to the wiring layer of the front structure 222. Each of the fourth bonding pads 225 may be bonded to a corresponding third bonding pad 217 among the third bonding pads 217 of the third bonding layer L3 by metal-to-metal bonding in hybrid bonding. By such metal- to-metal bonding in the hybrid bonding, an electrical connection may be made between the logic die 210 and the image sensor die 220.

The fourth dummy bonding pads 225H may penetrate the fourth bonding dielectric layer 224. The fourth dummy bonding pads 225H may be thermally connected to the third dummy bonding pads 217H of the third bonding layer L3, and to the wiring layer of the front structure 222. The fourth dummy bonding pads 225H may be electrically separated from other components within the image sensor 10A.

A bonding surface of each of the fourth bonding pads 225 and a bonding surface of each of the fourth dummy bonding pads 225H may be on a plane identical to a bonding surface of the fourth bonding dielectric layer 224. Side portions of each of the fourth bonding pads 225 and side portions of each of the fourth dummy bonding pads 225H may be surrounded by the fourth bonding dielectric layer 224. In an embodiment, the fourth bonding pads 225 and the fourth dummy bonding pads 225H may each have a width in a range of about 0.01 μm to about 30 μm in the horizontal direction (X direction and Y direction). In an embodiment, the fourth bonding pads 225 and the fourth dummy bonding pads 225H may each have a thickness in a range of about 0.1 μm to about 8 μm in a vertical direction (Z direction). In an embodiment, the fourth bonding pads 225 and the fourth dummy bonding pads 225H may each include copper or a copper alloy.

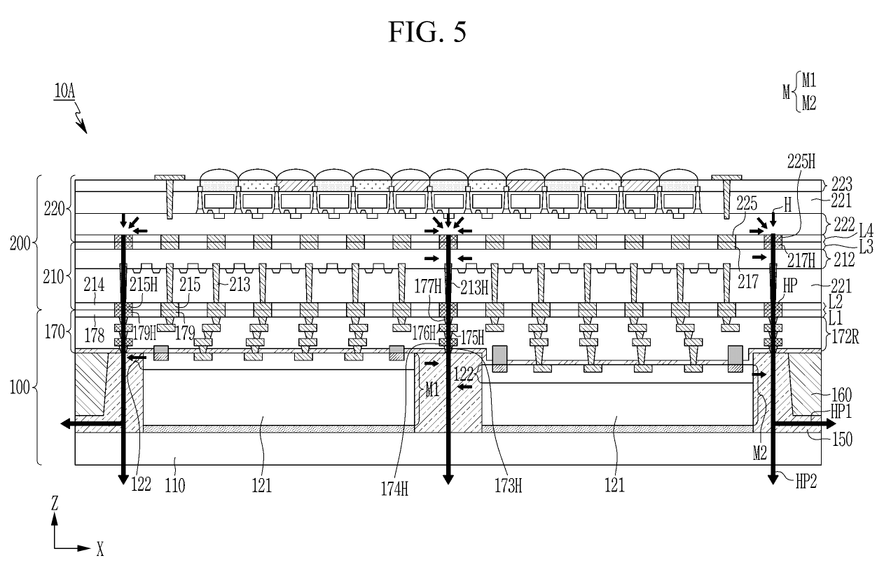

FIG. 5 is a cross-sectional view illustrating a heat dissipation path in the image sensor 10A of FIG. 2.

Referring to FIG. 5, the redistribution structure 170, the logic die 210, and the image sensor die 220 each include dummy structures, and the dummy structures may be thermally connected to the first molding material 150. The redistribution structure 170 may include first dummy vias 173H, first dummy lines 174H, second dummy vias 175H, second dummy lines 176H, third dummy vias 177H, and first dummy bonding pads 179H, which are sequentially arranged from the bottom as dummy structures. The logic die 210 may include second dummy bonding pads 215H, dummy through silicon vias 213H, dummy wiring layers in the front structure 212, and third dummy bonding pads 217H, which are sequentially arranged from the bottom as dummy structures. The image sensor die 220 may include fourth dummy bonding pads 225H and dummy wiring layers within the front structure 222, which are sequentially arranged from the bottom as dummy structures. The dummy wiring layers may include dummy vias and dummy lines connected with each other to form a heat flow path in each of the front structure 212 and the front structure 222. The dummy vias and lines in the dummy wiring layers do not serve as an electrical signal path or a power supply path. For example, the dummy vias and lines in the dummy wiring layers of the front structure 212 may be thermally connected to the third dummy bonding pads 217H in the third bonding layer L3 and the dummy through silicon vias 213H. For example, the dummy vias and lines in the dummy wiring layers of the front structure 222 may be thermally connected to the fourth dummy bonding pads 225H of the fourth bonding layer L4. In an embodiment, the dummy vias and lines in the dummy wiring layers of each of the front structures 212 and 222 may be placed therein to assist heat dissipation of the logic die 210 and the sensor die 220.

The heat H generated in the image sensor die 220 may be efficiently released to the outside through a first path HP1 (i.e., a first heat flow path) passing through the dummy structures of the image sensor die 220, the dummy structures of the logic die 210, the dummy structures of the redistribution structure 170, and the first molding material 150, or through a second path HP2 (i.e., a second heat flow path) passing through the dummy structures of the image sensor die 220, the dummy structures of the logic die 210, the dummy structures of the redistribution structure 170, the first molding material 150, and the support substrate 110. The heat H generated in the logic die 210 may be efficiently dissipated to the outside through the first path HP1 passing through the dummy structures of the logic die 210, the dummy structures of the redistribution structure 170, and the first molding material 150, or through the second path HP2 passing through the dummy structures of the logic die 210, the dummy structures of the redistribution structure 170, the first molding material 150, and the support substrate 110. The heat H generated from the memory dies M may be efficiently released to the outside through the first path HP1 passing through the first molding material 150, or through the second path HP2 passing through the first molding material 150 and the support substrate 110.

FIGS. 6A and 6B are plan views showing an image sensor 10A according to embodiments. FIG. 6A is a view showing the positions of a first memory die M1, a second memory die M2, first alignment marks AK1, second alignment marks AK2, third alignment marks AK3, and fourth alignment marks AK4 on a plane. FIG. 6B is a view showing the positions of a first memory die M1, a second memory die M2, a third memory die M3, a fourth memory die M4, first alignment marks AK1, second alignment marks AK2, third alignment marks AK3, and fourth alignment marks AK4 on a plane.

Referring to FIG. 6A, the second alignment marks AK2 of the redistribution structure 170 may be overlapped with the first memory die M1 and the second memory die M2 in the vertical direction (Z direction). The footprint of the second alignment marks AK2 may be included within the footprint of the first memory die M1 and the footprint of the second memory die M2. Each of the second alignment marks AK2 of the redistribution structure 170 may be overlapped with a corresponding first alignment mark AK1 among the first alignment marks AK1 of each of the first and second memory dies M1 and M2.

The third alignment marks AK3 of the redistribution structure 170 and the fourth alignment marks AK4 of the logic die 210 may not be overlapped with the first memory die M1 and the second memory die M2 in the vertical direction (Z direction). The footprint of the third alignment marks AK3 and the footprint of the fourth alignment marks AK4 may not be included within the footprint of the first memory die M1 and the footprint of the second memory die M2. Each of the third alignment marks AK3 of the redistribution structure 170 may be overlapped with a corresponding fourth alignment marks AK4 among the fourth alignment marks AK4 of the logic die 210.

Referring to FIG. 6B, the second alignment marks AK2 of the redistribution structure 170 may be overlapped with the first memory die M1, the second memory die M2, the third memory die M3, and the fourth memory die M4 in the vertical direction (Z direction). The footprint of the second alignment marks AK2 may be included within the footprint of the first memory die M1, the footprint of the second memory die M2, the footprint of the third memory die M3, and the footprint of the fourth memory die M4. Each of the second alignment marks AK2 of the redistribution structure 170 may be overlapped with a corresponding first alignment mark AK1 among the first alignment marks AK1 of each of the first to fourth memory dies M1 to M4.

The third alignment marks AK3 of the redistribution structure 170 and the fourth alignment marks AK4 of the logic die 210 may not be overlapped with the first memory die M1, the second memory die M2, the third memory die M3, and the fourth memory die M4 in the vertical direction (Z direction). The footprints of the third alignment marks AK3 and the footprints of the fourth alignment marks AK4 may not be included within the footprint of the first memory die M1, the footprint of the second memory die M2, the footprint of the third memory die M3, and the footprint of the fourth memory die M4. Each of the third alignment marks AK3 of the redistribution structure 170 may be overlapped with a corresponding fourth alignment mark AK4 among the fourth alignment marks AK4 of the logic die 210.

The redistribution structure 170 according to the present disclosure may include the second alignment marks AK2 for alignment with the first alignment marks AK1 of the memory dies M, and the third alignment marks AK3 for alignment with the fourth alignment marks AK4 of the image sensor package 200. The second alignment marks AK2 are disposed within the footprint of the memory dies M in the vertical direction (Z direction), and the third alignment marks AK3 may be disposed outside the footprint of the memory dies M in the vertical direction (Z direction). By using a redistribution structure 170 including the arrangement of the second alignment marks AK2 and the arrangement of the third alignment marks AK3, it may be possible to align between the logic die 210 in the image sensor package 200 and memory dies M having a relatively smaller size in the horizontal direction (X direction and Y direction) than a size of the logic die 210 in the horizontal direction (X direction and Y direction), thereby allowing the electrical paths between the memory dies M and the logic die 210 to be accurately formed.

Also, although two or four memory dies M are illustrated in FIGS. 6A and 6B, the present disclosure is not limited thereto, and the image sensor 10A including a greater number of memory dies M may be included within the scope of the present disclosure.

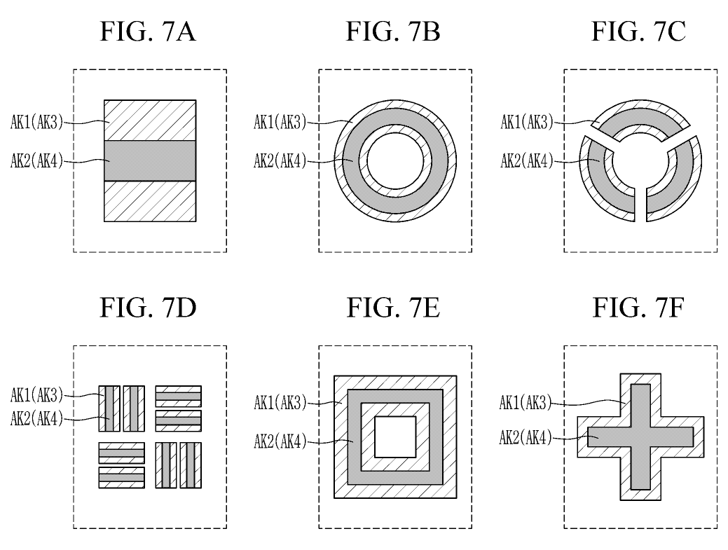

FIGS. 7A to 7F are plan views showing alignment marks AK1, AK2, AK3, and AK4 according to embodiments.

Referring to FIGS. 7A to 7F, each of the second alignment marks AK2 may overlap a corresponding first alignment mark AK1 among the first alignment marks AK1. Through alignment between the first alignment marks AK1 of the memory dies M and the second alignment marks AK2 of the redistribution structure 170, it is possible to determine whether alignment of the memory dies M and the redistribution structure 170 has been accurately achieved. In an embodiment, using the alignment between the first alignment marks AK1 and the second alignment marks A2, the redistribution structure 170 may be accurately aligned to each of the memory dies M. Each of the fourth alignment marks AK4 of the logic die 210 may be overlapped with the corresponding third alignment mark AK3 among the third alignment marks AK3 of the redistribution structure 170. Through the alignment between the third alignment marks AK3 and the fourth alignment marks AK4, it may be determined whether the alignment of the redistribution structure 170 and the image sensor package 200 has been accurately achieved. In an embodiment, using the alignment between the third alignment marks AK3 and the fourth alignment marks AK4, the image sensor package 200 may be accurately aligned with the redistribution structure 170. In an embodiment, the first alignment marks AK1, the second alignment marks AK2, the third alignment marks AK3, and the fourth alignment marks AK4 may each have a polygonal, elongated, ring-shaped, polygonal-frame-shaped, cruciform, or circular arc shape.

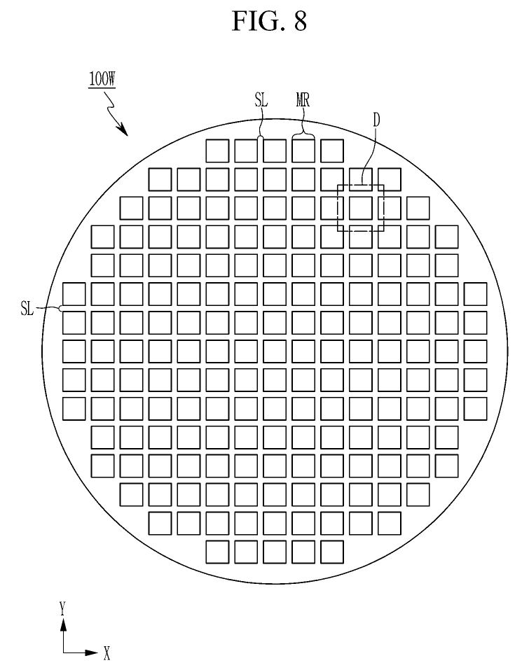

FIGS. 8 to 20 are drawings for illustrating a method of manufacturing memory packages 100 according to an embodiment.

FIG. 8 is a plan view showing a wafer 110W on which the memory packages 100 as shown in FIG. 1 may be formed.

Referring to FIG. 8, the wafer 110W may include main chip regions MR and a scribe lane SL that partitions the main chip regions MR. Hereinafter, a method of manufacturing memory packages 100 according to an embodiment will be described based on a cross-sectional view obtained by cutting region D of the first wafer 100W in a vertical direction (Z direction).

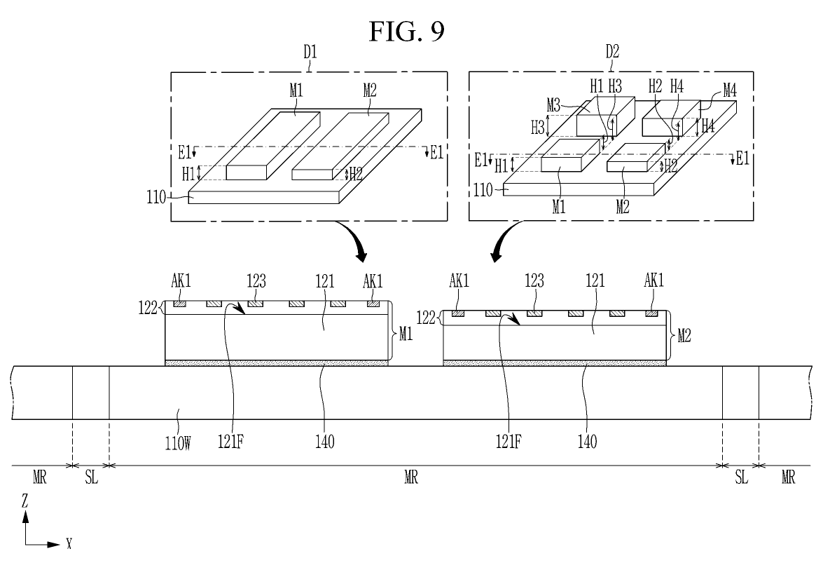

FIG. 9 is a cross-sectional view illustrating a step of attaching memory dies M on the wafer 110W. FIG. 9 is a cross-sectional view taken along line E1-E1 for two Examples D1 and D2 of region D of FIG. 8.

With reference to FIG. 9, in D1, the memory dies M may include a first memory die M1 and a second memory die M2. In D2, the memory dies M may include the first memory die M1, the second memory die M2, the third memory die M3, and the fourth memory die M4.

The memory dies M may be attached on the wafer 110W using the adhesive members 140. In an embodiment, the adhesive member 140 may include a die attach film (DAF). In an embodiment, the adhesive member 140 may include a thermal interface material (TIM). The TIM may be inserted between the support substrate 110 and the memory dies M, and may enhance thermal coupling between the support substrate 110 and the memory dies M. The TIM may serve to fill an air layer at the contact surface between the support substrate 110 and the memory dies M, thereby reducing thermal contact resistance. In an embodiment, the substrate 110 may correspond to the wafer 110W.

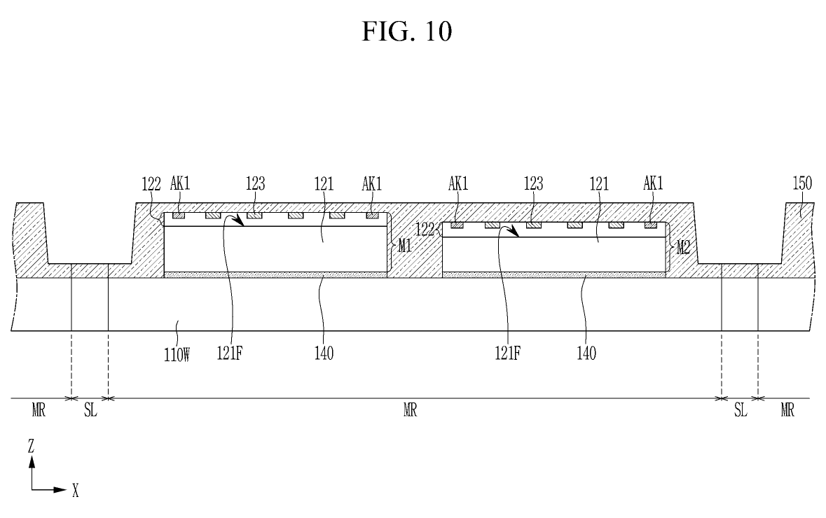

FIG. 10 is a cross-sectional view illustrating a step of covering the memory dies M on the wafer 110W with the first molding material 150.

Referring to FIG. 10, the memory dies M on the wafer 110W may be covered with the first molding material 150. The exposed surface of the wafer 110W, and the side portions and upper surfaces of the memory dies M may be covered with the first molding material 150 by a deposition process. The first molding material 150 may be conformally formed along the exposed surface of the wafer 110W, and along the side portions and upper surfaces of the memory dies M. In an embodiment, the deposition process may be performed by a chemical vapor deposition (CVD) process or a physical vapor deposition (PVD) process. In an embodiment, the first molding material 150 may include or may be formed of an inorganic dielectric material. In an embodiment, the first molding material 150 may include a high-k dielectric material. In an embodiment, the first molding material 150 may include aluminum oxide, aluminum nitride, boron nitride, silicon carbide, silicon nitride, carbon allotrope, or a mixture thereof.

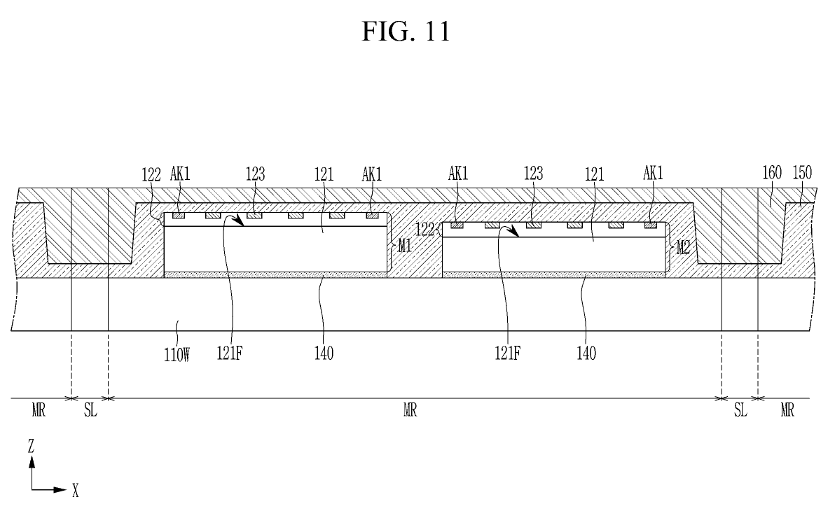

FIG. 11 is a cross-sectional view showing a step of molding the second molding material 160 on the first molding material 150.

Referring to FIG. 11, the first molding material 150 may be covered with the second molding material 160. In an embodiment, the process of molding with the second molding material 160 may include a compression molding or transfer molding process. In an embodiment, the second molding material 160 may include an organic dielectric material. In an embodiment, the second molding material 160 may include an EMC.

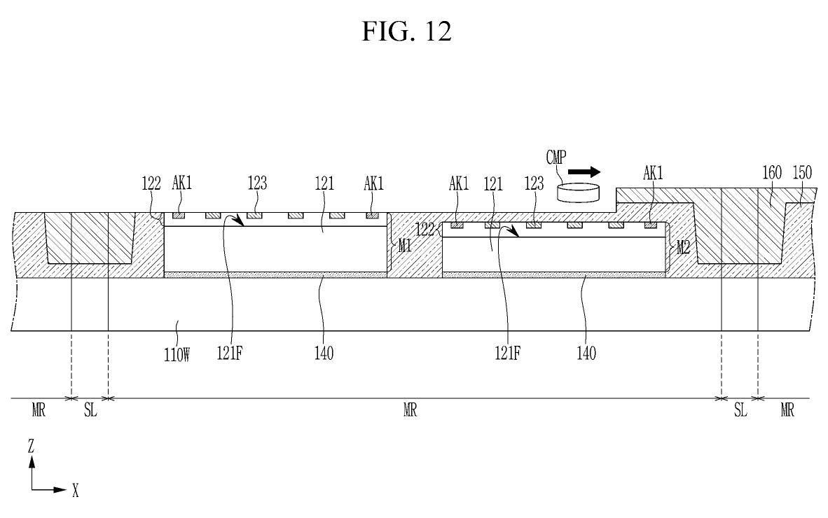

FIG. 12 is a cross-sectional view illustrating a step of performing a chemical mechanical polishing (CMP) process on the first molding material 150 and the second molding material 160.

Referring to FIG. 12, a CMP process may be performed to planarize the upper surface of the first molding material 150 and the upper surface of the second molding material 160. After performing the CMP process, the upper surface of the memory die M having the greatest height in the vertical direction among the memory dies M may be exposed. The upper surface of the memory die M having the greatest height in the vertical direction among the memory dies M may be on the same plane in the vertical direction (Z direction) as the upper surface of the first molding material 150 and the upper surface of the second molding material 160. Upper surfaces of the memory dies M other than the memory die M having the greatest height in the vertical direction among the memory dies M, may be covered by the first molding material 150.

FIG. 13 is a cross-sectional view illustrating a step of exposing the upper surface of the memory dies M other than the memory die M having the greatest height in the vertical direction among the memory dies M.

Referring to FIG. 13, the first molding material 150 on the memory dies M other than the memory die M having the greatest height in the vertical direction among the memory dies M may be removed. The process of removing the first molding material 150 may be performed by an etching process. After performing the etching process, openings OP may be formed in the first molding material 150. The openings OP may be formed on the memory dies M other than the memory die M having the greatest height in the vertical direction among the memory dies M.

When a height difference between the memory dies M is small, the first molding material 150 on the memory dies M may be entirely removed by a CMP process, and an etching process may not be performed.

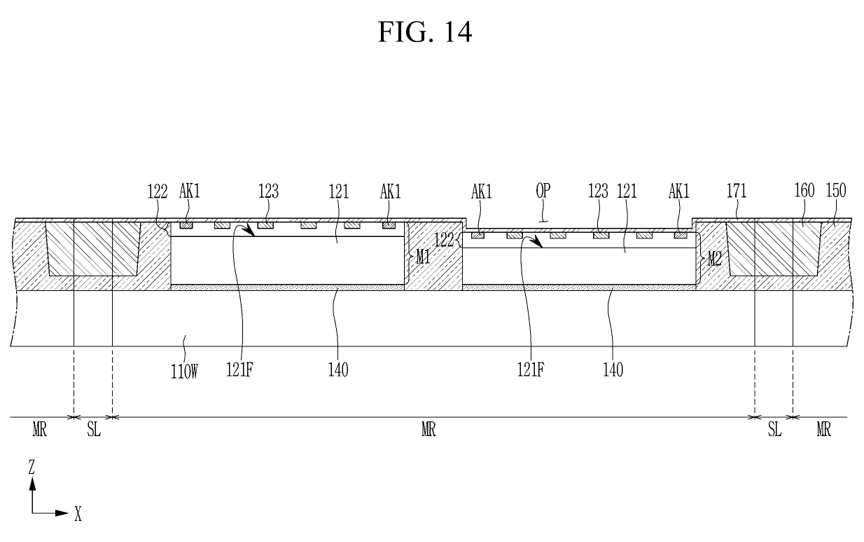

FIG. 14 is a cross-sectional view illustrating a step of depositing an etch stop layer 171.

Referring to FIG. 14, an etch stop layer 171 may be formed on the upper surfaces of the memory dies M, the upper surface of the first molding material 150, inner walls of the openings OP of the first molding material 150, and the upper surface of the second molding material 160. In an embodiment, a deposition process of the etch stop layer 171 may be performed by an ALD process or a CVD process. In an embodiment, the etch stop layer 171 may include silicon nitride. In an embodiment, the etch stop layer 171 may include SiN, SiCN, or SiON. In an embodiment, the etch stop layer 171 may be conformally formed on the upper surfaces of the memory dies M, the upper surface of the first molding material 150, inner walls of the openings OP of the first molding material 150, and the upper surface of the second molding material 160. The etch stop layer 171 may have a thickness not sufficient to completely fill the openings OP, and an upper surface of a first portion of the etch stop layer 171 on the first memory die M1 may be higher than an upper surface of a second portion of the etch stop layer 171 on the second memory die M2.

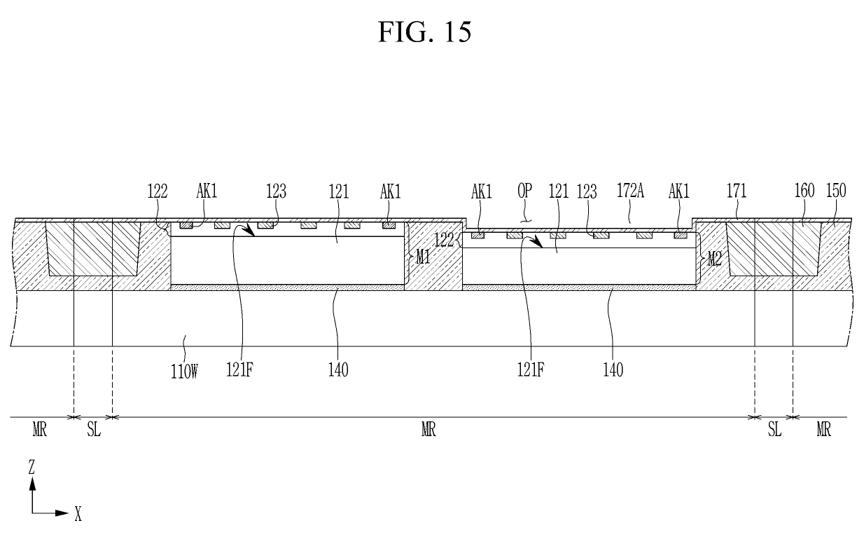

FIG. 15 is a cross-sectional view illustrating a step of depositing a first dielectric 172A in the openings OP of the first molding material 150.

Referring to FIG. 15, in order to compensate for the height difference between the memory dies M, the first dielectric 172A may be deposited in the openings OP of the first molding material 150. In an embodiment, the deposition process of the first dielectric 172A may be a CVD process. In an embodiment, the first dielectric 172A may include an inorganic dielectric material. In an embodiment, the first dielectric 172A may include SiO2, SiOC, SiOH, SiOCH, or a low-k dielectric layer. In an embodiment, a layer of a dielectric may be formed on the etch stop layer 171 so that the etch stop layer 171 and the layer of the dielectric completely fill the openings, and then may be planarized using an etch-back or CMP process to form the first dielectric 172A. An upper surface of the first dielectric 172A may be coplanar with an upper surface of the etch stop layer 171 disposed on the first memory die M1, the first molding material 150, and the second molding material 160.

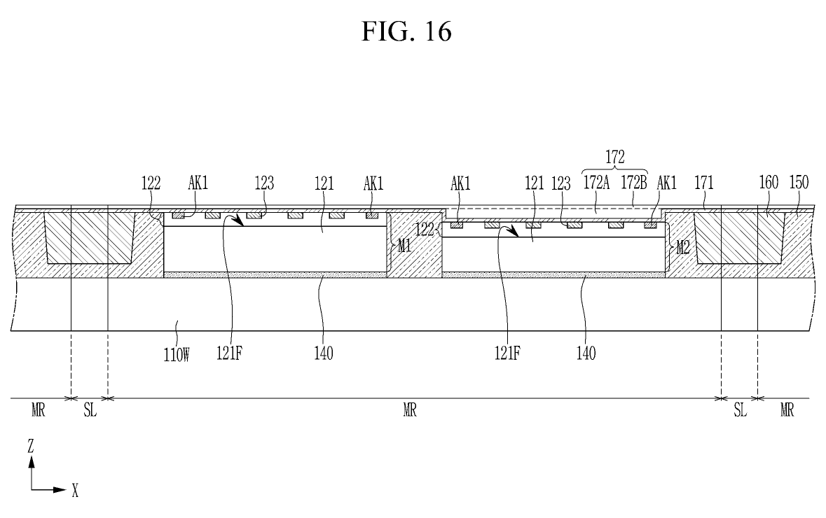

FIG. 16 is a cross-sectional view illustrating a step of depositing a second dielectric 172B on an etch stop layer 171 and on the first dielectric 172A.

Referring to FIG. 16, a second dielectric 172B may be deposited on the etch stop layer 171 and on the first dielectric 172A. In an embodiment, the deposition process of the second dielectric 172B may be performed by a CVD process. In an embodiment, the second dielectric 172B may include an inorganic dielectric material. In an embodiment, the second dielectric 172B may include SiO2, SiOC, SiOH, SiOCH, or a low-k dielectric layer. In an embodiment, the second dielectric 172B and the first dielectric 172A may be formed of the same inorganic dielectric material.

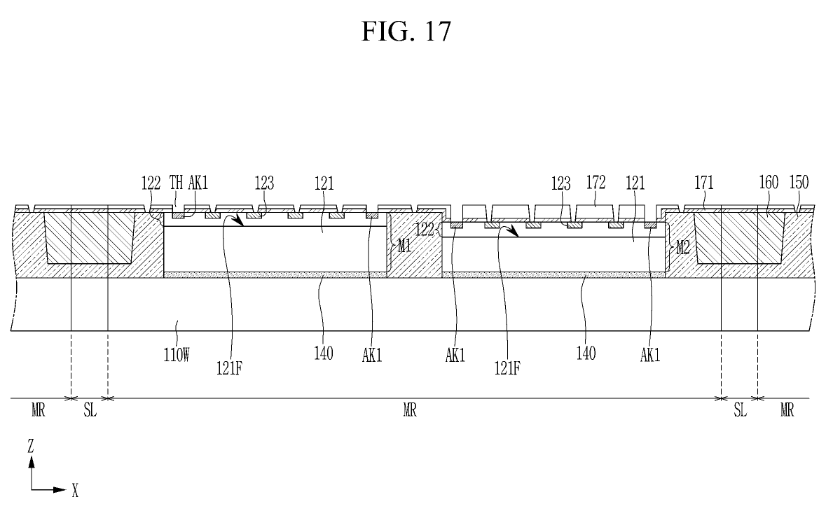

FIG. 17 is a cross-sectional view illustrating a step of forming holes TH in the dielectric 172.

Referring to FIG. 17, holes TH may be formed in the dielectric 172. In an embodiment, the process of forming holes TH may be performed by an etching process.

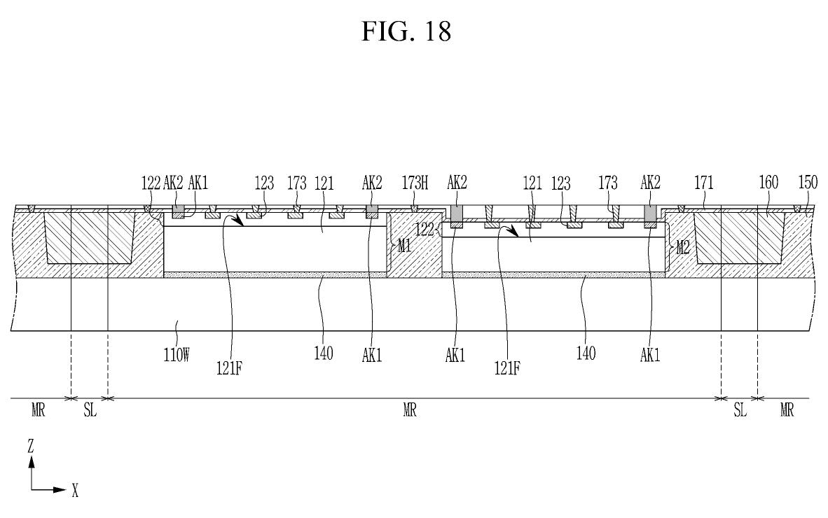

FIG. 18 is a cross-sectional view illustrating a step of filling holes TH with a conductive material.

Referring to FIG. 18, the insides of the holes TH may be filled with a conductive material so that first redistribution vias 173, first dummy vias 173H, and second alignment marks AK2 may be formed. In an embodiment, the process of filling the holes TH may be performed by a sputtering process or an electroplating process. In an embodiment, the first redistribution vias 173, the first dummy vias 173H, and the second alignment marks AK2 may include at least one of copper, aluminum, silver, tin, gold, nickel, lead, titanium, and alloys thereof.

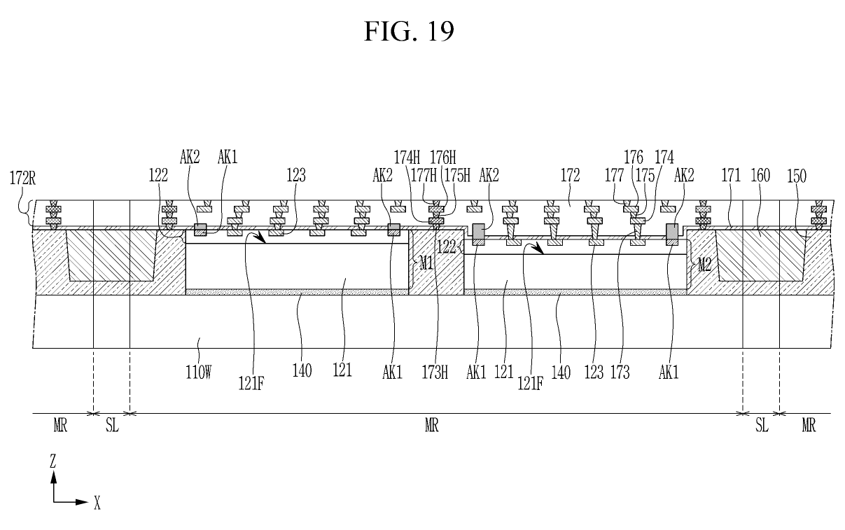

FIG. 19 is a cross-sectional view illustrating a step of forming the redistribution layer 172R.

Referring to FIG. 19, a dielectric 172 may be deposited, holes may be formed in the dielectric 172, and the process of filling the holes TH with a conductive material may be repeatedly performed, thereby forming a redistribution layer 172R.

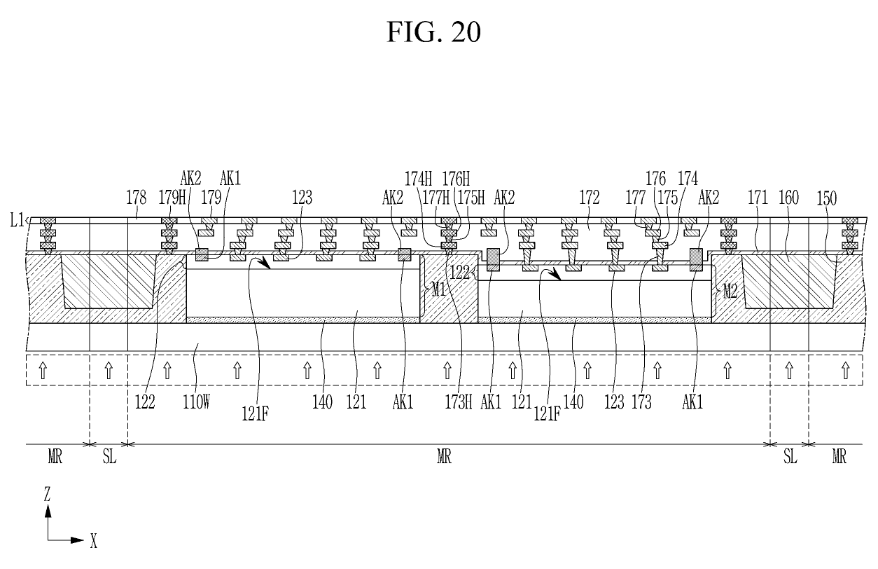

FIG. 20 is a cross-sectional view illustrating a step of forming the first bonding layer L1.

Referring to FIG. 20, a first bonding dielectric layer 178 may be formed on the redistribution layer 172R. The first bonding dielectric layer 178 may be continuously and conformally formed along the redistribution layer 172R. In an embodiment, the first bonding dielectric layer 178 may include a silicon compound. In an embodiment, the first bonding dielectric layer 178 may include silicon oxide or silicon nitride. In an embodiment, the first bonding dielectric layer 178 may include SiO2, SiN, or SiCN. In an embodiment, the first bonding dielectric layer 178 may be formed through an ALD process or a CVD process.

Subsequently, a photoresist may be applied to the first bonding dielectric layer 178, and the photoresist may be exposed and developed to form a photoresist pattern. In an embodiment, the photoresist may be formed by performing a spin coating process. In an embodiment, the photoresist may include an organic polymer resin including a photoactive material.

Thereafter, the first bonding dielectric layer 178 exposed from the photoresist pattern may be etched using the photoresist pattern as an etching mask to form recess portions (e.g., holes) in the first bonding dielectric layer 178. The recessed portions may expose the third redistribution vias 177 and the third dummy vias 177H. In an embodiment, a process of etching the first bonding dielectric layer 178 may be performed by dry etching.

Thereafter, a seed metal layer may be formed on the first bonding dielectric layer 178. The seed metal layer may be continuously and conformally formed along the first bonding dielectric layer 178. In an embodiment, the seed metal layer may include copper or a copper alloy. In an embodiment, the seed metal layer may be formed by sputtering or an electroless plating process. In an embodiment, prior to the electroless plating process, a cleaning process or a metal catalyst activation pretreatment process may be performed.

Subsequently, a conductive material may be deposited on the seed metal layer. The conductive material may be deposited on the third redistribution vias 177 and the third dummy vias 177H exposed by the recessed portions formed in the first bonding dielectric layer 178. In an embodiment, the conductive material may include copper or a copper alloy. In an embodiment, the conductive material may be formed by electroplating. A conductive material may be formed by growing a metal film through electroplating from a previously formed seed metal layer. The conductive material may cover the upper surface of the first bonding dielectric layer 178 beyond the upper surface of the first bonding dielectric layer 178.

Afterwards, in order to match the level of the upper surface of the conductive material and the level of the upper surface of the first bonding dielectric layer 178, a CMP process may be performed on the conductive material covering the upper surface of the first bonding dielectric layer 178. After performing the CMP process, first bonding pads 179, first dummy bonding pads 179H, and third alignment marks AK3 may be formed to form the first bonding layer L1.

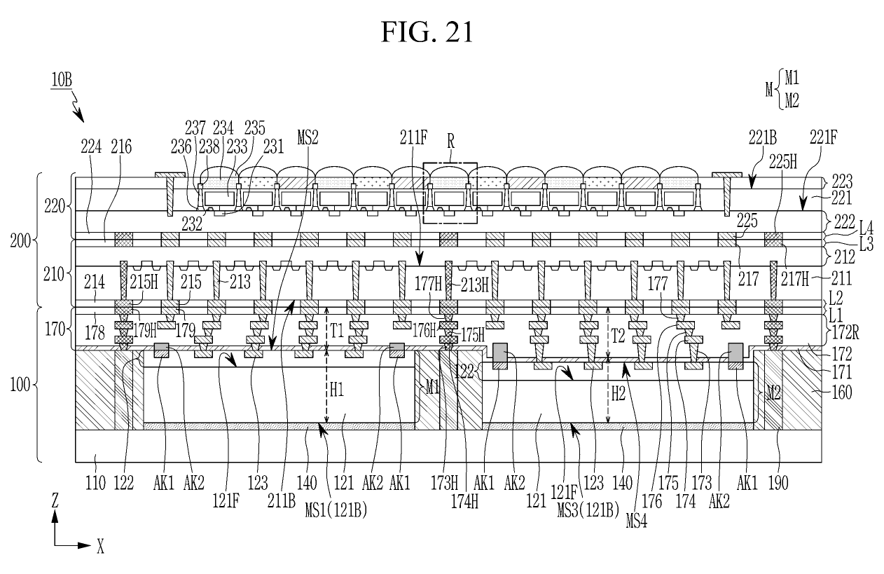

FIG. 21 is a cross-sectional view illustrating the image sensor 10B of an embodiment.

Referring to FIG. 21, the image sensor 10B may include dummy posts 190 in the memory package 100. Dummy posts 190 may be disposed on the support substrate 110. The dummy posts 190 may be disposed beside the memory dies M. The dummy posts 190 may be electrically separated from other components within the image sensor 10B. A side surface of the dummy posts 190 may be surrounded by the molding material 160. Each of the dummy posts 190 may be thermally connected to the support substrate 110 and to a corresponding first dummy via 173H among the first dummy vias 173H of the redistribution structure 170.

For contents other than those described for the image sensor 10B of an embodiment in FIG. 21, the contents described for the image sensor 10A of FIGS. 1 to 4 and FIGS. 6A and 6B, FIGS. 7A to 7F, and FIG. 8 may be applied.

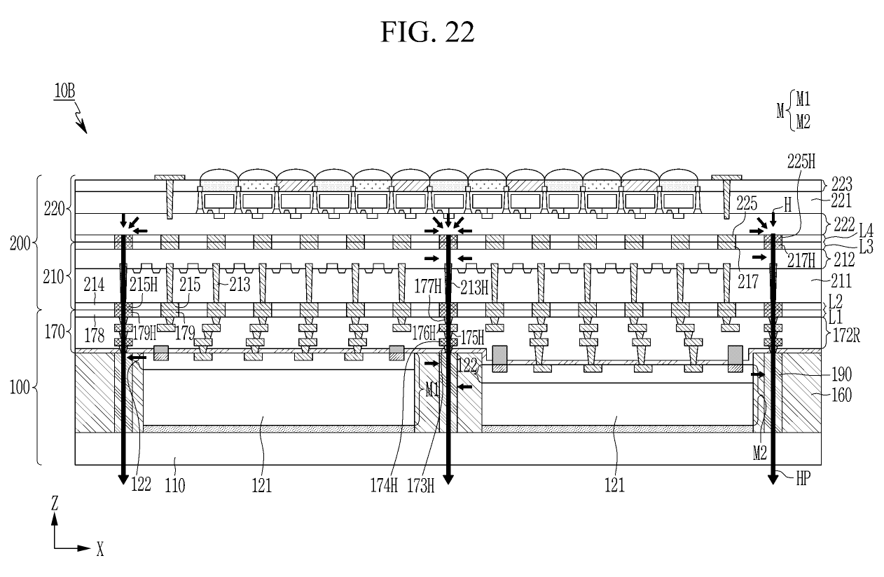

FIG. 22 is a cross-sectional view illustrating a heat dissipation path in the image sensor 10B of FIG. 21.

Referring to FIG. 22, the redistribution structure 170, the logic die 210, and the image sensor die 220 may each include dummy structures, and the dummy structures may be thermally connected to the dummy posts 190. The redistribution structure 170 may include first dummy vias 173H, first dummy lines 174H, second dummy vias 175H, second dummy lines 176H, third dummy vias 177H, and first dummy bonding pads 179H, which are sequentially arranged from the bottom as dummy structures. The logic die 210 may include second dummy bonding pads 215H, dummy through silicon vias 213H, dummy wiring layers within the front structure 212, and third dummy bonding pads 217H, which are sequentially arranged from the bottom as dummy structures. The image sensor die 220 may include fourth dummy bonding pads 225H and dummy wiring layers within the front structure 222, which are sequentially from the bottom as dummy structures.

The heat H generated in the image sensor die 220 may be efficiently dissipated to the outside through a path HP (i.e., a heat flow path) passing through the dummy structures of the image sensor die 220, the dummy structures of the logic die 210, the dummy structures of the redistribution structure 170, the dummy posts 190, and the support substrate 110. Heat H generated in the logic die 210 may be efficiently released to the outside through the path HP including the dummy structures of the logic die 210, the dummy structures of the redistribution structure 170, the dummy posts 190, and the support substrate 110. Heat H generated from the memory dies M may be efficiently dissipated to the outside through the path HP passing through the dummy posts 190 and the support substrate 110.

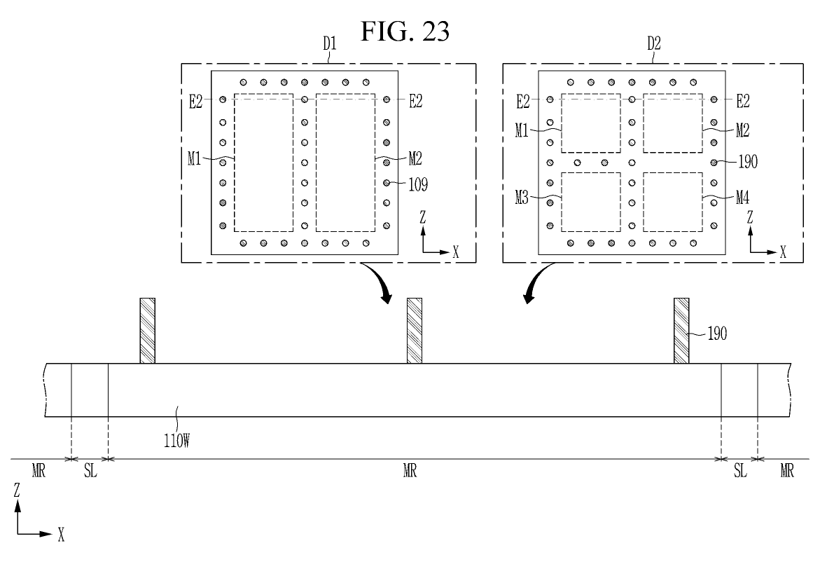

FIGS. 23 to 26 are cross-sectional views for illustrating a method of manufacturing the memory package 100 of the image sensor 10B of FIG. 21.

FIG. 23 is a cross-sectional view illustrating a step of forming dummy posts 190 on the wafer 110W. FIG. 23 is a cross-sectional view taken along line E2-E2 for two Examples D1 and D2, with respect to region D of FIG. 8. The Examples D1 and D2 are plan views illustrating embodiments of the dummy posts 190 disposed on the wafer 110W of FIG. 23. The description regarding the wafer 110W explained in FIG. 8 may be applied to the wafer 110W of FIG. 23.

Referring to FIG. 23, the dummy posts 190 may be formed on the wafer 110W. The dummy posts 190 may be formed by forming a seed metal layer on the wafer 110W, depositing a photoresist on the seed metal layer, selectively exposing and developing the photoresist to form a photoresist pattern including openings, and filling the openings with a conductive material. In an embodiment, the dummy posts 190 may be formed by performing an electroplating process. In an embodiment, the dummy posts 190 may include copper or a copper alloy.

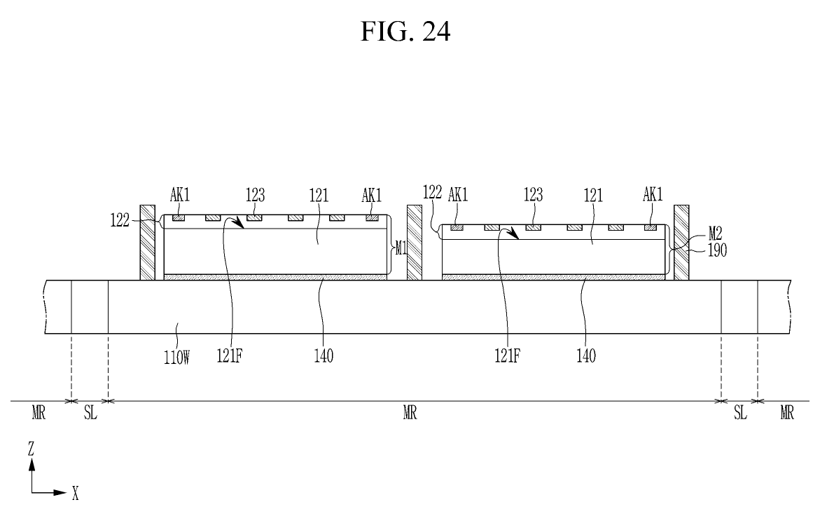

FIG. 24 is a cross-sectional view showing a step of attaching memory dies M on the wafer 110W. Referring to the Example D1 of FIG. 23, the positions on the wafer 110W where the memory dies M may be disposed can be identified in the plan view of FIG. 23.

Referring to FIGS. 23 and 24, in the Example D1, the memory dies M may include the first memory die M1 and the second memory die M2. In the Example D2, the memory dies M may include the first memory die M1, the second memory die M2, the third memory die M3, and the fourth memory die M4.

The memory dies M may be attached on the wafer 110W using the adhesive members 140. In an embodiment, the adhesive member 140 may include a DAF. In an embodiment, the adhesive member 140 may include a TIM. The TIM may be inserted between the support substrate 110 and the memory dies M, and may enhance thermal coupling between the support substrate 110 and the memory dies M. The TIM may serve to fill the air layer of the contact surface between the support substrate 110 and the memory dies M to reduce thermal contact resistance.

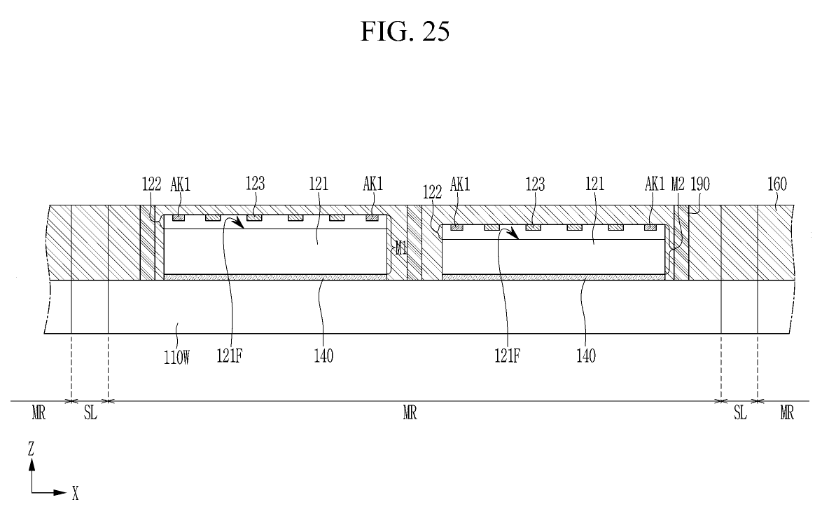

FIG. 25 is a cross-sectional view illustrating a step of molding the molding material 160 on the wafer 110W.

Referring to FIG. 25, the memory dies M and the dummy posts 190 on the wafer 110W may be covered by the molding material 160. In an embodiment, the process of molding with the molding material 160 may include a compression molding process or a transfer molding process. In an embodiment, the molding material 160 may include an organic dielectric material or an inorganic dielectric material. In an embodiment, the molding material 160 may include an EMC. In an embodiment, the molding material 160 may include a high-k dielectric material. In an embodiment, the molding material 160 may include aluminum oxide, aluminum nitride, boron nitride, silicon carbide, silicon nitride, a carbon allotrope, or a mixture thereof.

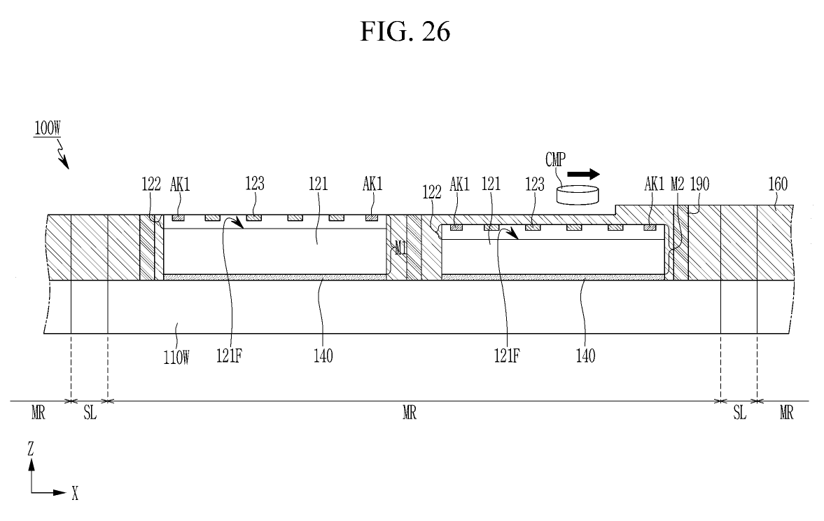

FIG. 26 is a cross-sectional view illustrating a step of performing a CMP process on the molding material 160.

Referring to FIG. 26, a CMP process may be performed so that the upper surface of the molding material 160 and the dummy posts 190 may be planarized. After performing the CMP process, the upper surface of the memory die M having the greatest height in the vertical direction among the memory dies M may be exposed. The upper surface of the memory die M having the greatest height in the vertical direction among the memory dies M may be on the same plane in the vertical direction (Z direction) as the upper surface of the molding material 160 and the upper surfaces of the dummy posts 190. Upper surfaces of memory dies M other than the memory die M having the greatest height in the vertical direction among the memory dies M may be covered by the molding material 160.

The method of manufacturing the memory package 100 of the image sensor 10A of FIG. 2 described in FIGS. 13 to 20 may be applied to the method of manufacturing the memory package 100 of the image sensor 10B of FIG. 21.

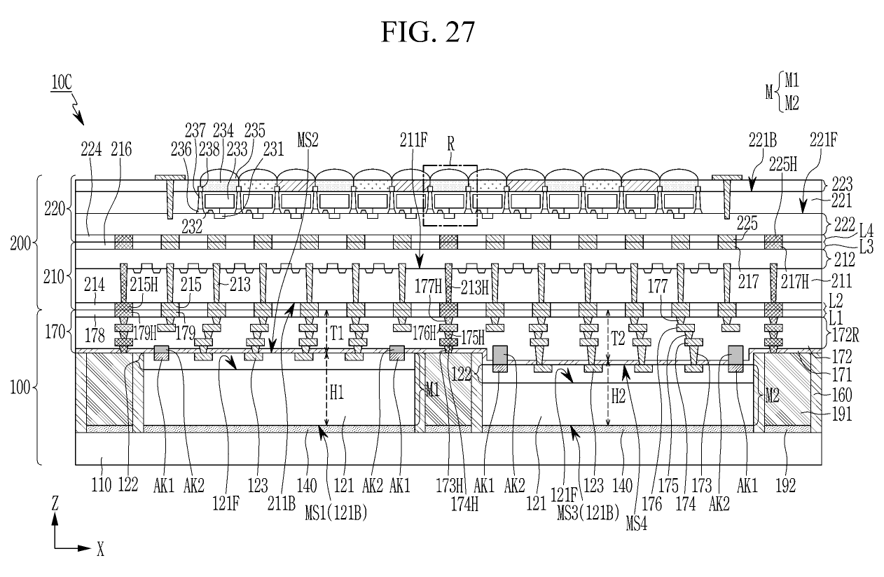

FIG. 27 is a cross-sectional view showing an image sensor 10C according to an embodiment.

Referring to FIG. 27, the image sensor 10C may include a heat dissipation structure 191 and an adhesive member 192 in the memory package 100. The heat dissipation structure 191 may be disposed on the support substrate 110. The heat dissipation structure 191 may be disposed beside the memory dies M. The heat dissipation structure 191 may be disposed next to the memory dies M. For example, the heat dissipation structure 191 may be adjacent to the opposite sides of each of the memory dies M. The heat dissipation structure 191 may be electrically separated from other components within the image sensor 10B. The heat dissipation structure 191 may penetrate the molding material 160. A side surface of the heat dissipation structure 191 may be surrounded by the molding material 160. The heat dissipation structure 191 may be thermally connected to the support substrate 110 and to a corresponding first dummy via 173H among the first dummy vias 173H of the redistribution structure 170. In an embodiment, the heat dissipation structure 191 may include a heat slug, a heat sink, or a heat spreader. In an embodiment, the heat dissipation structure 191 may include a conductive material having high thermal conductivity. In an embodiment, the heat dissipation structure 191 may include at least one of copper, aluminum, silver, tin, gold, nickel, lead, titanium, and alloys thereof. The heat dissipation structure 191 may be attached to the support substrate 110 by the adhesive member 192.

The heat dissipation structure 191 may extend in a horizontal direction (X direction and Y direction) along at least a portion of the side portions of the memory dies M. The heat dissipation structure 191 may be extended in a horizontal direction (X direction and Y direction) along at least a portion of each side portion among the side portions of the memory dies M. The heat dissipation structures 191 may be disposed with an interval therebetween. In an embodiment, the heat dissipation structures 191 may have a polygon, an elongated, or a polygonal frame shape.

For contents other than those described for the image sensor 10C of the example in FIG. 27, the contents described for the image sensor 10A in FIGS. 1 to 4 and FIGS. 6 to 8 may be applied.

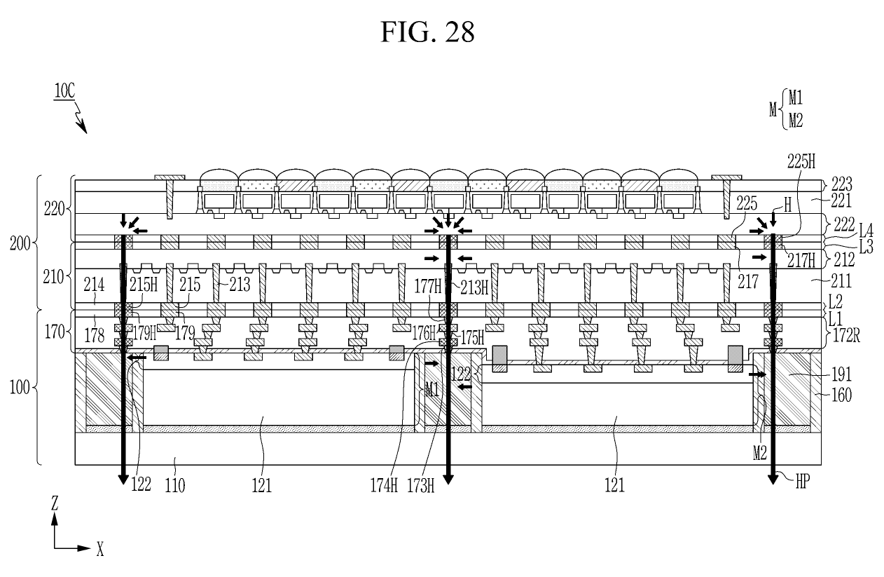

FIG. 28 is a cross-sectional view illustrating a heat dissipation path in the image sensor 10C of FIG. 21.

Referring to FIG. 28, the redistribution structure 170, the logic die 210, and the image sensor die 220 each include dummy structures, and the dummy structures may be thermally connected to the heat dissipation structure 191. The redistribution structure 170 may include first dummy vias 173H, first dummy lines 174H, second dummy vias 175H, second dummy lines 176H, third dummy vias 177H, and first dummy bonding pads 179H, which are sequentially arranged from the bottom as dummy structures. The logic die 210 may include second dummy bonding pads 215H, dummy through silicon vias 213H, dummy wiring layers within the front structure 212, and third dummy bonding pads 217H, which are sequentially arranged from the bottom as dummy structures. The image sensor die 220 may include fourth dummy bonding pads 225H and dummy wiring layers within the front structure 222, which are sequentially arranged from the bottom as dummy structures.

Heat H generated in the image sensor die 220 may be efficiently dissipated to the outside through a path HP (i.e., a heat flow path) passing through the dummy structures of the image sensor die 220, the dummy structures of the logic die 210, the dummy structures of the redistribution structure 170, the heat dissipation structure 191, and the support substrate 110. Heat H generated in the logic die 210 may be efficiently released to the outside through the path HP passing through the dummy structures of the logic die 210, the dummy structures of the redistribution structure 170, the heat dissipation structure 191, and the support substrate 110. Heat H generated in the memory dies M may be efficiently dissipated to the outside through the path HP passing through the heat dissipation structure 191 and the support substrate 110.

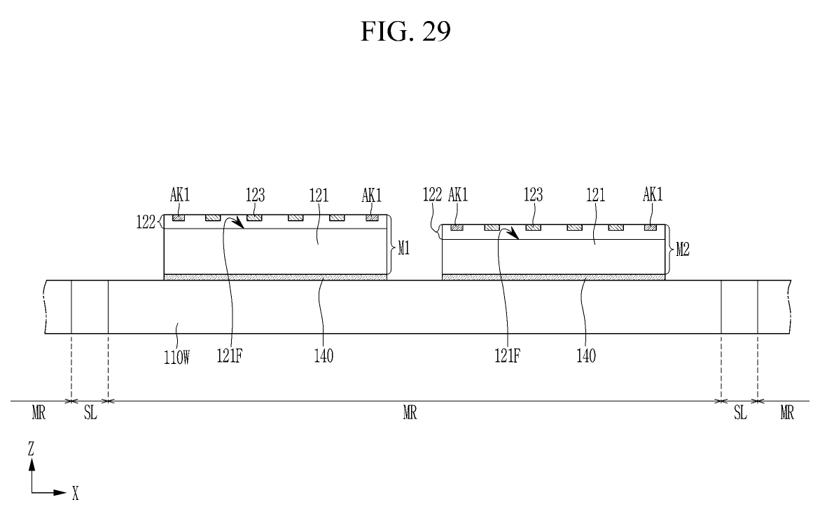

FIGS. 29 to 32 are cross-sectional views illustrating a method of manufacturing the memory package 100 of the image sensor 10C of FIG. 27.

FIG. 29 is a cross-sectional view illustrating a step of attaching memory dies M on the wafer 110W. The description regarding the wafer 110W explained in FIG. 8 may be applied to the wafer 110W of FIG. 29.

Referring to FIG. 29, the memory dies M may be attached on the wafer 110W using the adhesive members 140. In an embodiment, the adhesive members 140 may include a DAF. In an embodiment, the adhesive members 140 may include a TIM. The TIM may be inserted between the support substrate 110 and the memory dies M, and may enhance thermal coupling between the support substrate 110 and the memory dies M. The TIM may fill the air layer of the contact surface between the support substrate 110 and the memory dies M to reduce the thermal contact resistance.

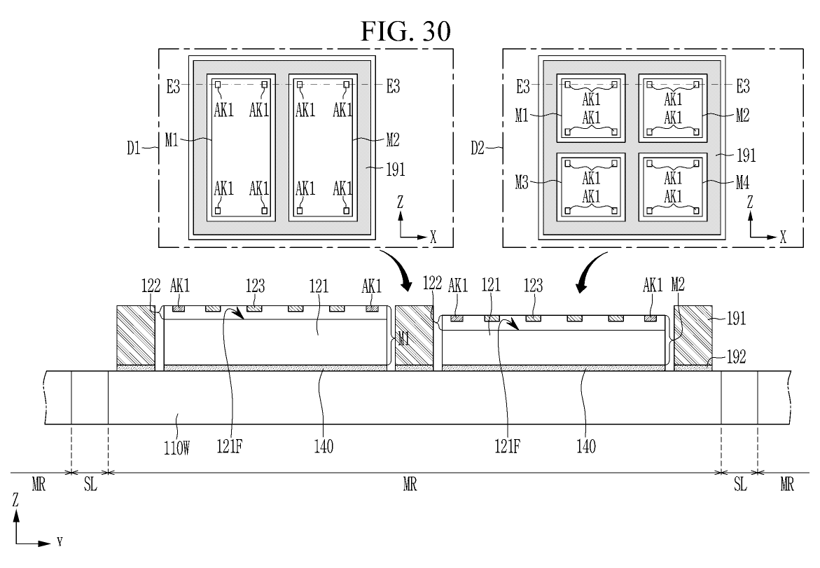

FIG. 30 is a cross-sectional view illustrating a step of attaching a heat dissipation structure 191 to the wafer 110W. FIG. 30 is a cross-sectional view taken along line E3-E3 for two Examples D1 and D2 of region D in FIG. 8. The Examples D1 and D2 are plan views illustrating embodiments of the heat dissipation structure 191 disposed on the wafer 110W of FIG. 30.

Referring to FIG. 30, the heat dissipation structure 191 may be attached on the wafer 110W. The heat dissipation structure 191 may be attached on the wafer 110W using the adhesive member 192. In an embodiment, the adhesive member 192 may include a DAF. In an embodiment, the adhesive member 192 may include a TIM. The TIM may be inserted between the support substrate 110 and the heat dissipation structure 191, and may enhance thermal coupling between the support substrate 110 and the heat dissipation structure 191. The TIM may fill the air layer of the contact surface between the support substrate 110 and the heat dissipation structure 191 to reduce thermal contact resistance.

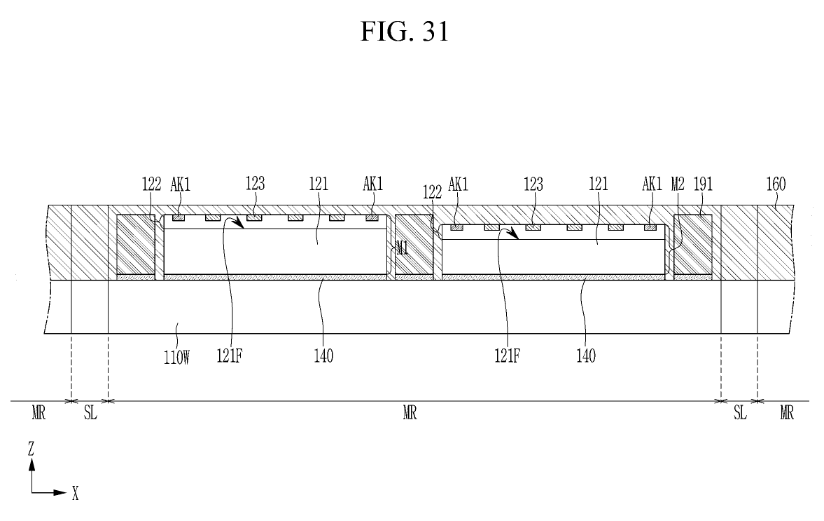

FIG. 31 is a cross-sectional view illustrating a step of molding the molding material 160 on the wafer 110W.

Referring to FIG. 31, the memory dies M and the heat dissipation structure 191 on the wafer 110W may be covered by the molding material 160. In an embodiment, the process of molding with molding material 160 may include a compression molding process or a transfer molding process. In an embodiment, the molding material 160 may include an organic dielectric material or an inorganic dielectric material. In an embodiment, the molding material 160 may include an EMC. In an embodiment, the molding material 160 may include a high-k dielectric material. In an embodiment, the molding material 160 may include aluminum oxide, aluminum nitride, boron nitride, silicon carbide, silicon nitride, a carbon allotrope, or a mixture thereof.

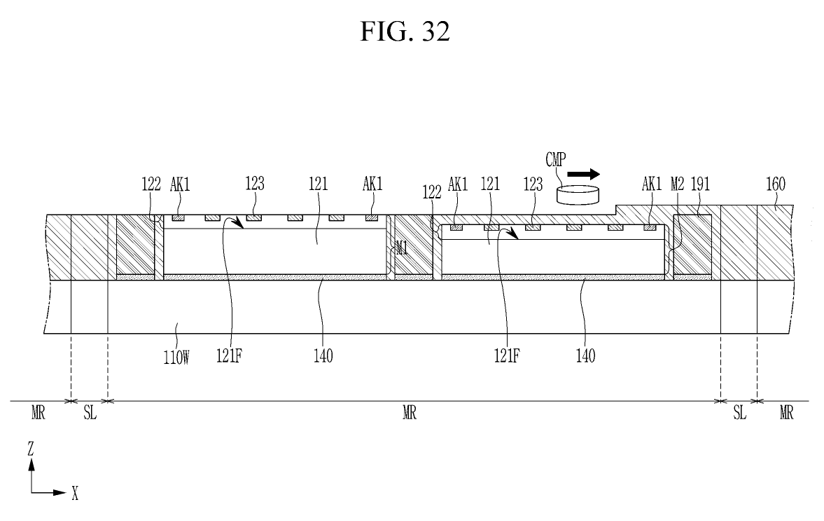

FIG. 32 is a cross-sectional view illustrating a step of performing a CMP process on the molding material 160.

Referring to FIG. 32, the CMP process may be performed to planarize the upper surface of the molding material 160. After performing the CMP process, the upper surface of the memory die M having the greatest height in the vertical direction among the memory dies M may be exposed. An upper surface of the memory die M having the greatest height in a vertical direction among the memory dies M may be on the same plane in the vertical direction (Z direction) as an upper surface of the molding material 160 and an upper surface of the heat dissipation structure 191. Upper surfaces of the memory dies M other than the memory die M having the greatest height in the vertical direction among the memory dies M, may be covered by the molding material 160.

The method for manufacturing the memory package 100 of the image sensor 10A of FIG. 2 described in FIGS. 13 to 20 may be applied to the method for manufacturing the memory package 100 of the image sensor 10C of FIG. 27 described later.

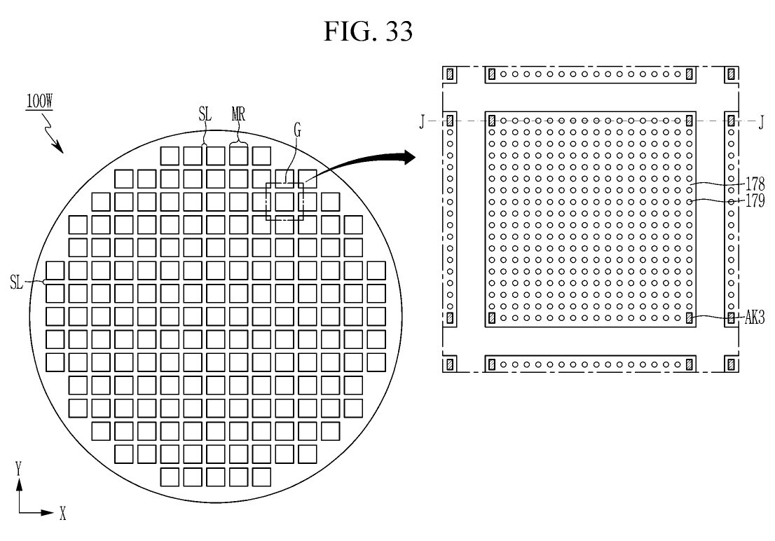

FIGS. 33 to 39 are diagrams for explaining a method of manufacturing an image sensor 10 by bonding a first wafer 100W including memory packages 100 of an embodiment and a second wafer 200W including an image sensor package 200 of an embodiment. The image sensor 10 may be manufactured by performing a wafer-to-wafer bonding process.

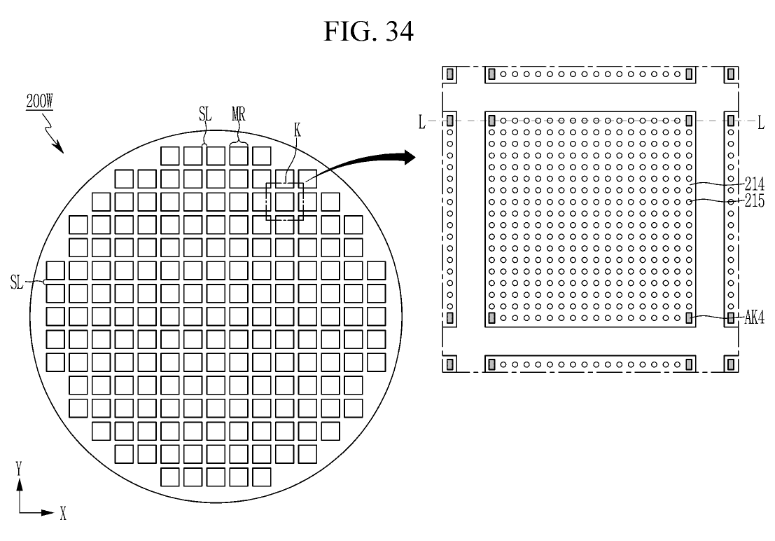

FIG. 33 is a plan view showing the first wafer 100W on which the memory packages 100 are formed. FIG. 34 is a plan view illustrating the second wafer 200W on which the image sensor packages 200 are formed.

Referring to FIGS. 33 and 34, the first wafer 100W may include main chip regions MR on which the memory packages 100 are formed, and scribe lanes SL partitioning the main chip regions MR. The second wafer 200W may include main chip regions MR in which the image sensor package 200 is formed, and a scribe lane SL for partitioning the main chip regions MR. A hybrid bonding process may be applied to bond the first wafer 100W and the second wafer 200W, and in order to perform the hybrid bonding process, each of the memory packages 100 of the first wafer 100W and the corresponding image sensor package 200 among the image sensor packages 200 of the second wafer 200W need to be accurately aligned. Referring to region G of the first wafer 100W and region K of the second wafer 200W, a memory package 100 may include third alignment marks AK3 and the image sensor package 200 may include fourth alignment marks AK4, so as to determine whether each of the memory packages 100 and a corresponding image sensor package 200 among the image sensor packages 200 are aligned suitably to perform hybrid bonding. The third alignment marks AK3 are disposed at corners of the memory package 100, and the fourth alignment marks AK4 may be disposed at corners of the image sensor package 200.

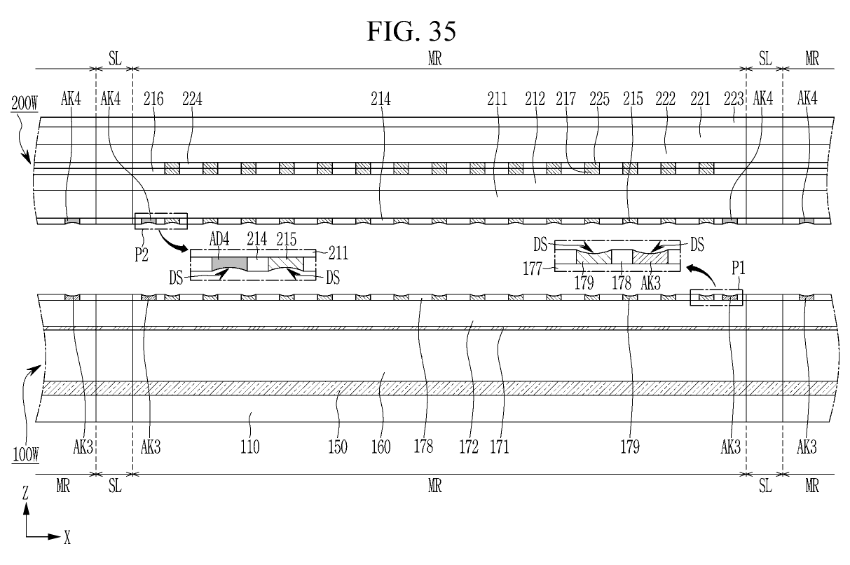

FIGS. 35 to 39 are cross-sectional views illustrating the region G of the first wafer 100W of FIG. 33 cut along line J-J, and the region K of the second wafer 200W of FIG. 34 cut along line L-L.

FIG. 35 is a cross-sectional view illustrating a step in which the first wafer 100W and the second wafer 200W are aligned.

Referring to FIG. 35, the first wafer 100W, on which a CMP process has been performed on the bonding surface, and the second wafer 200W, on which a CMP process has been performed on the bonding surface, may be aligned.

As described with reference to FIG. 20, referring to region P1 of the bonding surface of the first wafer 100W after performing the CMP process, due to the difference in the etch selectivity between the film quality of the first bonding dielectric layer 178 and the film quality of the first bonding pad 179, and due to the influence of mechanical processing, dishing DS in which the central region of the first bonding pad 179 is removed more than the peripheral region of the first bonding pad 179 may be formed in the first bonding pads 179 of the first wafer 100W. In addition, dishing DS may be formed in the third alignment mark AK3 due to the difference in the etch selectivity between the film quality of the first bonding dielectric layer 178 and the film quality of the third alignment mark AK3, and due to the influence of mechanical processing.

In addition, referring to the region P2 of the bonding surface of the second wafer 200W after performing the CMP process, due to the difference in the etch selectivity between the film quality of the second bonding dielectric layer 214 and the film quality of the second bonding pad 215, and due to the influence of mechanical processing, dishing DS, in which the central region of the second bonding pad 215 is removed more than the peripheral region of the second bonding pad 215, may be formed in the second bonding pads 215 of the second wafer 200W. Dishing DS may also be formed in the fourth alignment mark AK4 due to the difference in the etch selectivity between the film quality of the second bonding dielectric layer 214 and the film quality of the fourth alignment mark AK4, and due to the influence of mechanical processing.

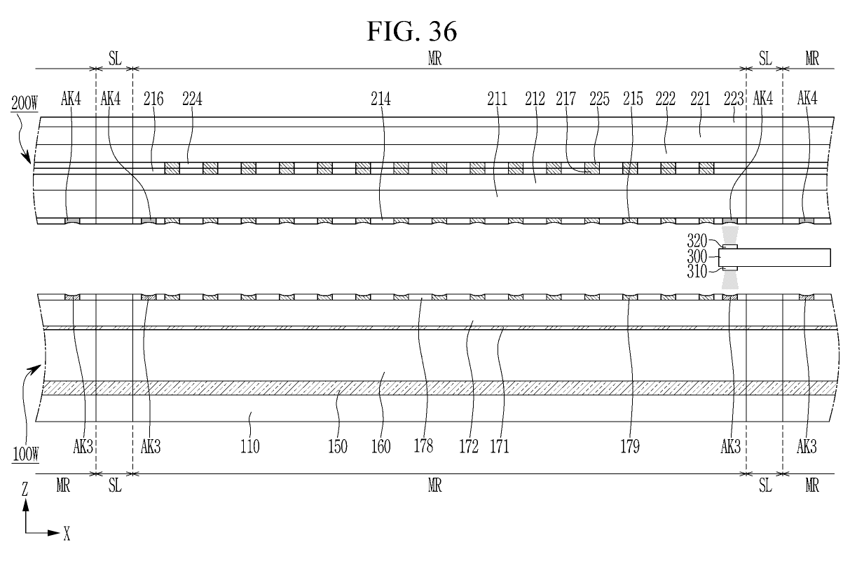

FIG. 36 is a cross-sectional view illustrating a step of measuring alignment between the third alignment mark AK3 of the first wafer 100W and the fourth alignment mark AK4 of the second wafer 200W.

Referring to FIG. 36, the imaging device 300 may be positioned between the first wafer 100W and the second wafer 200W. The imaging device 300 may include a first camera 310 disposed to face the first wafer 100W and a second camera 320 disposed to face the second wafer 200W. The first camera 310 may photograph the third alignment marks AK3 of the first wafer 100W, and the second camera 320 may photograph the fourth alignment marks AK4 of the second wafer 200W. Each of the third alignment marks AK3 and the corresponding fourth alignment mark AK4 among the fourth alignment marks AK4 may be photographed simultaneously or sequentially by the first camera 310 and the second camera 320, and it may be determined whether each of the third alignment marks AK3 and the corresponding fourth alignment mark AK4 among the fourth alignment marks AK4 are aligned.

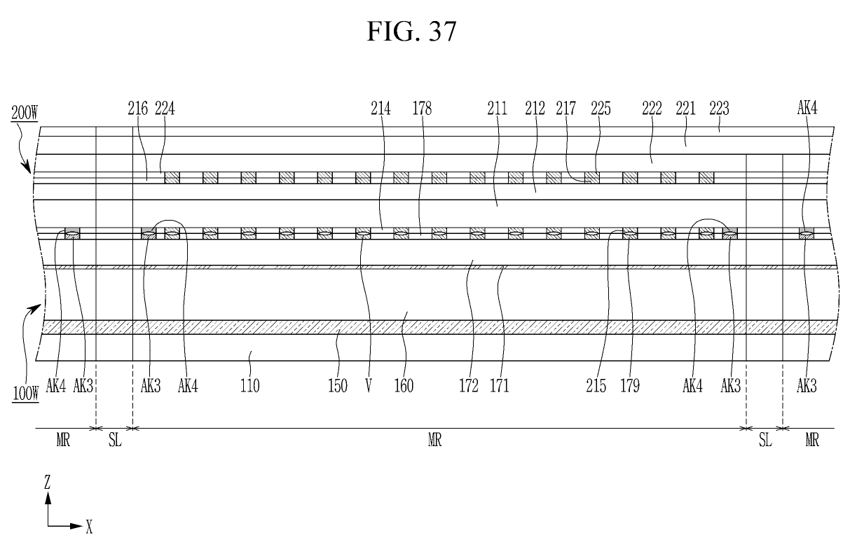

FIG. 37 is a cross-sectional view illustrating a step of bonding the first bonding dielectric layer 178 of the first wafer 100W and the second bonding dielectric layer 214 of the second wafer 200W.

Referring to FIG. 37, the first bonding dielectric layer 178 of the first wafer 100W and the second bonding dielectric layer 214 of the second wafer 200W physically contact each other, and may be pre-bonded. The first bonding dielectric layer 178 of the first wafer 100W and the second bonding dielectric layer 214 of the second wafer 200W may be bonded to each other by covalent bonding. At this time, each first bonding pad 179 among the first bonding pads 179 of the first wafer 100W and the corresponding second bonding pad 215 among the second bonding pads 215 of the second wafer 200W, and each third alignment mark AK3 among the third alignment marks AK3 of the first wafer 100W and the corresponding fourth alignment mark AK4 among the fourth alignment marks AK4 of the second wafer 200W may be in a state of not being bonded to each other, having a space V formed by mutual dishing DS.

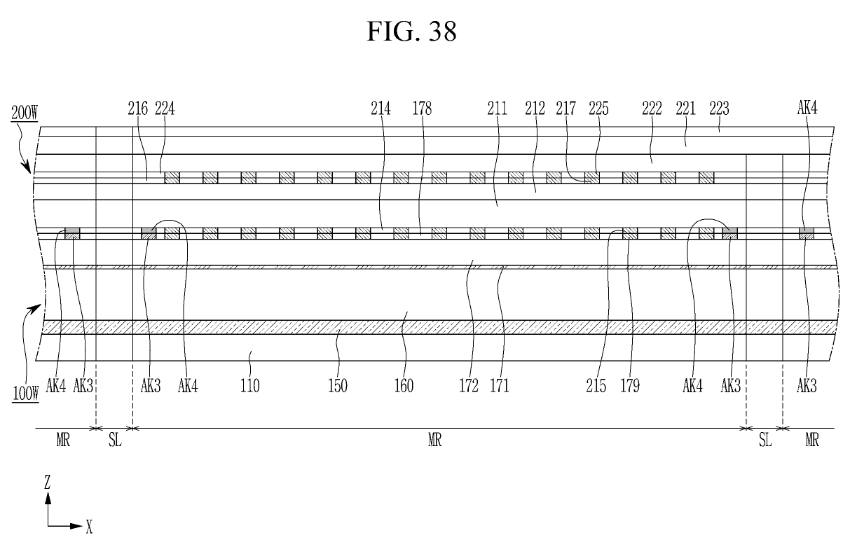

FIG. 38 is a cross-sectional view illustrating a step of performing annealing on a pre-bonded first wafer 100W and second wafer 200W.

Referring to FIG. 38, an annealing process is performed, and each first bonding pad 179 among the first bonding pads 179 of the first wafer 100W and a corresponding second bonding pad 215 among the second bonding pads 215 of the second wafer 200W, and each third alignment mark AK3 among the third alignment marks AK3 of the first wafer 100W and a corresponding fourth alignment mark AK4 among the fourth alignment marks AK4 of the second wafer 200W may be bonded to each other. Due to the difference in coefficient of thermal expansion (CTE) between the dielectric, which is the material of the bonding dielectric layer, and the metal, which is the material of the bonding pads (or alignment marks), during the annealing process, each first bonding pad 179 among the first bonding pads 179 of the first wafer 100W and the corresponding second bonding pad 215 among the second bonding pads 215 of the second wafer 200W, as well as each third alignment mark AK3 among the third alignment marks AK3 of the first wafer 100W and the corresponding fourth alignment mark AK4 among the fourth alignment marks AK4 of the second wafer 200W, may expand to fill the space V and be bonded to each other. In an embodiment, during the annealing process, the pressure may be less than about 30 MPa. In an embodiment, the annealing process may be performed at a temperature of about 100°C to about 500°C.

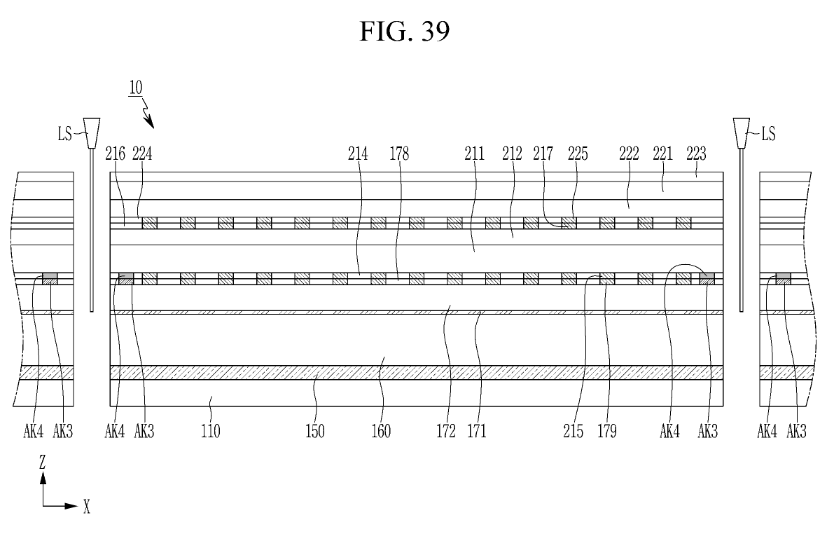

FIG. 39 is a cross-sectional view illustrating a step of performing a singulation process to form individual image sensors 10 on the bonded first wafer 100W and second wafer 200W.

Referring to FIG. 39, the first wafer 100W and the second wafer 200W bonded may be singulated into an image sensor 10 using singulation equipment LS. In an embodiment, the singulation equipment LS may include a blade, laser, or plasma etching equipment. The second molding material 160 including a material having excellent mechanical properties covers around the first molding material 150, and since the area cut by the second molding material 160 during the singulation process is large, the reliability of the singulation process may be improved. For example, the singulation process may be applied to the second molding material 160 having an excellent mechanical property, and thus the reliability of the singulation process may be secured.

Although preferred examples of the present invention have been described as above, the present invention is not limited thereto, and it is apparent that various modifications may be made within the scope of the claims, the detailed description of the invention, and the accompanying drawings, and these also belong to the scope of the present invention.

What is claimed is:

1. An image sensor comprising:
a first memory die having a first height in a vertical direction;
a second memory die disposed next to the first memory die and having a second height in the vertical direction, wherein the second height is less than the first height;
a molding material surrounding a sidewall of each of the first memory die and the second memory die, wherein the vertical direction is perpendicular to an upper surface of the molding material;
a redistribution structure disposed on the first memory die, on the second memory die, and on the molding material and including:
a first bonding dielectric layer; and
a plurality of first bonding pads penetrating the first bonding dielectric layer,
wherein the redistribution structure has a first thickness in the vertical direction on the first memory die, and a second thickness in the vertical direction on the second memory die, the second thickness being greater than the first thickness;
a logic die disposed on the redistribution structure and including:
a second bonding dielectric layer directly bonded to the first bonding dielectric layer; and
a plurality of second bonding pads penetrating the second bonding dielectric layer and directly bonded to the plurality of first bonding pads; and
an image sensor die on the logic die.

2. The image sensor of claim 1,
wherein the logic die includes an artificial intelligence (AI) processor, and
wherein the first memory die and the second memory die are of different types.

3. The image sensor of claim 1,
wherein the first memory die and the second memory die each include a plurality of first alignment marks,
wherein the redistribution structure includes a plurality of second alignment marks, and
wherein each of the plurality of second alignment marks is aligned with a corresponding first alignment mark among the plurality of first alignment marks.

4. The image sensor of claim 3,
wherein the plurality of second alignment marks overlap the first memory die and the second memory die in the vertical direction.

5. The image sensor of claim 1,
wherein the redistribution structure includes a plurality of third alignment marks in the first bonding dielectric layer,
wherein the logic die includes a plurality of fourth alignment marks in the second bonding dielectric layer, and
wherein each of the plurality of third alignment marks is aligned to a corresponding fourth alignment mark among the plurality of fourth alignment marks.

6. The image sensor of claim 5,
wherein a footprint of each of the plurality of third alignment marks and the plurality of fourth alignment marks is disposed at an outside of a footprint of each of the first memory die and the second memory die in the vertical direction.

7. The image sensor of claim 1,
wherein the redistribution structure includes an etch stop layer contacting the first memory die, the second memory die, and the molding material.

8. An image sensor comprising:
a memory package; and
an image sensor package on the memory package,
wherein the memory package comprises:
a molding material;
a plurality of memory dies including a first memory die having an upper surface coplanar with an upper surface of the molding material and a second memory die having an upper surface lower than the upper surface of the molding material and adjacent to the first memory die, the plurality of memory dies having different heights in a vertical direction perpendicular to the upper surface of the molding material; and
a redistribution structure disposed on the molding material and on the plurality of memory dies, contacting an upper surface of each of the plurality of memory dies, having a thickness profile with different thickness values in the vertical direction, and including a first bonding dielectric layer and a plurality of first bonding pads penetrating the first bonding dielectric layer, wherein a thickness of the redistribution structure on the first memory die is lower than a thickness of the redistribution structure on the second memory die,
wherein the image sensor package comprises:
a logic die including a second bonding dielectric layer directly bonded to the first bonding dielectric layer and a plurality of second bonding pads penetrating the second bonding dielectric layer and directly bonded to the plurality of first bonding pads; and
an image sensor die on the logic die.

9. The image sensor of claim 8,
wherein the image sensor further includes a heat dissipation structure penetrating the molding material and arranged next to each memory die of the plurality of memory dies.

10. The image sensor of claim 9,
wherein the redistribution structure includes a plurality of first dummy structures thermally connected to the heat dissipation structure,
wherein the logic die includes a plurality of second dummy structures thermally connected to the plurality of first dummy structures of the redistribution structure, and
wherein the image sensor die includes a plurality of third dummy structures thermally connected to the plurality of second dummy structures of the logic die.

11. The image sensor of claim 9,
wherein the heat dissipation structure is a plurality of dummy posts penetrating the molding material in the vertical direction.

12. The image sensor of claim 9,
wherein the heat dissipation structure extends along a side portion of each memory die of the plurality of memory dies in the vertical direction.

13. An image sensor comprising:
a first semiconductor package and a second semiconductor package on the first semiconductor package,
wherein the first semiconductor package comprises:
a dummy die;
a first memory die on the dummy die, the first memory die including a first surface in contact with the dummy die and a second surface opposite to the first surface, the first memory die having a first height between the first surface and the second surface;
a second memory die on the dummy die and next to the first memory die, the second memory die including a third surface in contact with the dummy die and a fourth surface opposite to the third surface, the second memory die having a second height between the third surface and the fourth surface, the second height being less than the first height;
a redistribution structure on the first memory die and on the second memory die, the redistribution structure including an etch stop layer, a redistribution layer on the etch stop layer, and a first bonding layer on the redistribution layer, the etch stop layer being in contact with the second surface and the fourth surface, the first bonding layer including a first bonding dielectric layer and a plurality of first bonding pads penetrating the first bonding dielectric layer, the redistribution structure having a first thickness on the first memory die and a second thickness on the second memory die, and the second thickness being greater than the first thickness;
a first molding material surrounding a sidewall of each of the first memory die and the second memory die and disposed in a space between the dummy die and the redistribution structure; and
a second molding material surrounding a sidewall of the first molding material and disposed in a space between the dummy die and the redistribution structure, and
wherein the second semiconductor package comprises:
a logic die including a second bonding layer; and
an image sensor die on the logic die,
wherein the second bonding layer includes:
a second bonding dielectric layer directly bonded to the first bonding dielectric layer; and
a plurality of second bonding pads penetrating the second bonding dielectric layer and directly bonded to the plurality of first bonding pads.

14. The image sensor of claim 13,
wherein the first molding material includes a high-k dielectric material.

15. The image sensor of claim 13,
wherein the first molding material includes aluminum oxide, aluminum nitride, boron nitride, silicon carbide, silicon nitride, carbon allotrope, or a combination thereof.

16. The image sensor of claim 13,
wherein the second molding material includes an epoxy molding compound (EMC).

17. The image sensor of claim 13,
wherein the redistribution structure, the logic die, and the image sensor die each include a plurality of dummy structures, and
wherein the first molding material is thermally connected to the plurality of dummy structures.

18. The image sensor of claim 13,
wherein the dummy die is a heat dissipation structure, and
wherein the first molding material is thermally connected to the dummy die.

19. The image sensor of claim 13,
wherein the redistribution layer includes:
an inorganic dielectric;
a plurality of redistribution lines in the inorganic dielectric; and
a plurality of redistribution vias in the inorganic dielectric.

20. The image sensor of claim 19,
wherein the inorganic dielectric is disposed on the fourth surface of the second memory die,
wherein a lower surface of the inorganic dielectric on the fourth surface of the second memory die is lower than an upper surface of the first molding material, and
wherein an upper surface of the first memory die is coplanar with the upper surface of the first molding material.
